(19) United States
(12) Patent Application Publication
(10) Pub. No.: US 2014/0353526 A1
(43) Pub. Date: Dec. 4, 2014

(54) METHOD AND SYSTEM FOR FORMING HIGH ACCURACY PATTERNS USING CHARGED PARTICLE BEAM LITHOGRAPHY

(71) Applicant: D2S, Inc., San Jose, CA (US)

(72) Inventor: Akira Fujimura, Saratoga, CA (US)

(73) Assignee: D2S, INC., San Jose, CA (US)

(21) Appl. No.: 14/454,140

(22) Filed: Aug. 7, 2014

Related U.S. Application Data
(63) Continuation-in-part of application No. 14/106,584, filed on Dec. 13, 2013.
Application No. 14/106,584 is a continuation of application No. 13/924,019, filed on Jun. 21, 2013, now Pat. No. 8,612,901.
Application No. 13/924,019 is a continuation of application No. 13/168,954, filed on Jun. 25, 2011, now Pat. No. 8,473,875.
Application No. 14/106,584 is a continuation-in-part of application No. 13/723,181, filed on Dec. 20, 2012, now Pat. No. 8,609,306.
Application No. 13/723,181 is a continuation of application No. 13/282,446, filed on Oct. 26, 2011, now Pat. No. 8,354,207.
Application No. 13/282,446 is a continuation of application No. 12/540,322, filed on Aug. 12, 2009, now Pat. No. 8,057,970.
Application No. 12/540,322 is a continuation-in-part of application No. 12/202,364, filed on Sep. 1, 2008, now Pat. No. 7,759,026.
Application No. 12/202,364 is a continuation-in-part of application No. 12/473,241, filed on May 27, 2009, now Pat. No. 7,754,401.
Application No. 12/473,241 is a continuation-in-part of application No. 12/202,364, filed on Sep. 1, 2008, now Pat. No. 7,759,026.
(60) Provisional application No. 61/392,477, filed on Oct. 13, 2010.
(60) Provisional application No. 61/224,849, filed on Jul. 10, 2009.

(51) Int. Cl. H01J 37/317; H01J 37/147; G06F 17/50; H01J 37/302

(52) U.S. Cl. CPC H01J 37/3177; H01J 37/3026; H01J 37/1472; G06F 17/5081; H01J 2237/3172
USPC 250/492.21; 716/53

(57) ABSTRACT

A method and system for fracturing or mask data preparation for charged particle beam lithography are disclosed in which a plurality of charged particle beam shots is determined that will form a pattern on a surface using a multi-beam charged particle beam writer, where the sensitivity of the pattern on the surface to manufacturing variation is reduced by increasing edge slope.

### RELATED APPLICATIONS

This application is a continuation-in-part of U.S. patent application Ser. No. 14/106,584 filed on Dec. 13, 2013 entitled “Method and System For Forming High Accuracy Patterns Using Charged Particle Beam Lithography”, which is hereby incorporated by reference for all purposes. U.S. patent application Ser. No. 14/106,584 1) is a continuation of U.S. patent application Ser. No. 13/924,019 filed on Jun. 21, 2013 entitled “Method and System For Forming Patterns Using Charged Particle Beam Lithography With Multiple Exposure Passes” and issued as U.S. Pat. No. 8,612,901; which 2) is a continuation of U.S. patent application Ser. No. 13/168,954 entitled “Method and System For Forming High Accuracy Patterns Using Charged Particle Beam Lithography” filed on Jun. 25, 2011 and issued as U.S. Pat. No. 8,473,875; which 3) claims priority to U.S. Provisional Patent Application Ser. No. 61/392,477 filed on Oct. 13, 2010 and entitled “Method for Integrated Circuit Manufacturing and Mask Data Preparation Using Curvilinear Patterns”; and 4) is related to U.S. patent application Ser. No. 13/168,953 filed on Jun. 25, 2011 and issued as U.S. Pat. No. 8,703,389, entitled “Method and System for Forming Patterns with Charged Particle Beam Lithography”; all of which are hereby incorporated by reference for all purposes.

U.S. patent application Ser. No. 14/106,584: 5) is also a continuation-in-part of U.S. patent application Ser. No. 13/723,181 filed on Dec. 20, 2012 entitled “Method For Forming Circular Patterns On A Surface” and issued as U.S. Pat. No. 8,609,306; which 6) is a continuation of U.S. patent application Ser. No. 13/282,446 filed on Oct. 26, 2011 entitled “Method, Device, And System For Forming Circular Patterns On A Surface” and issued as U.S. Pat. No. 8,354,207; which 7) is a continuation of U.S. patent application Ser. No. 12/540,322 filed on Aug. 12, 2009 entitled “Method and System For Forming Circular Patterns On a Surface” and issued as U.S. Pat. No. 8,057,970, all of which are hereby incorporated by reference for all purposes.

U.S. patent application Ser. No. 12/540,322: 8) is a continuation-in-part of U.S. patent application Ser. No. 12/202,364 filed Sep. 1, 2008, entitled “Method and System For Manufacturing a Reticle Using Character Projection Particle Beam Lithography” and issued as U.S. Pat. No. 7,759,026; 9) is a continuation-in-part of U.S. patent application Ser. No. 12/473,241 filed May 27, 2009, entitled “Method for Manufacturing a Surface and Integrated Circuit Using Variable Shaped Beam Lithography” and issued as U.S. Pat. No. 7,754,401; 10) claims priority from U.S. Provisional Patent Application Ser. No. 61/224,849 filed Jul. 10, 2009, entitled “Method and System for Manufacturing Circular Patterns On a Surface And Integrated Circuit”; and 11) is related to U.S. patent application Ser. No. 12/540,321 filed Aug. 12, 2009, entitled “Method For Fracturing Circular Patterns and For Manufacturing a Semiconductor Device” and issued as U.S. Pat. No. 8,017,288; all of which are hereby incorporated by reference for all purposes.

### BACKGROUND OF THE DISCLOSURE

The present disclosure is related to lithography, and more particularly to the design and manufacture of a surface which may be a reticle, a wafer, or any other surface, using charged particle beam lithography.

In the production or manufacturing of semiconductor devices, such as integrated circuits, optical lithography may be used to fabricate the semiconductor devices. Optical lithography is a printing process in which a lithographic mask or photomask manufactured from a reticle is used to transfer patterns to a substrate such as a semiconductor or silicon wafer to create the integrated circuit (I.C.). Other substrates could include flat panel displays, holographic masks, or even other reticles. While conventional optical lithography uses a light source having a wavelength of 193 nm, extreme ultraviolet (EUV) or X-ray lithography are also considered types of optical lithography in this application. The reticle or multiple reticles may contain a circuit pattern corresponding to an individual layer of the integrated circuit, and this pattern can be imaged onto a certain area on the substrate that has been coated with a layer of radiation-sensitive material known as photoresist or resist. Once the patterned layer is transferred the layer may undergo various other processes such as etching, ion-implantation (doping), metallization, oxidation, and polishing. These processes are employed to finish an individual layer in the substrate. If several layers are required, then the whole process or variations thereof will be repeated for each new layer. Eventually, a combination of multiples of devices or integrated circuits will be present on the substrate. These integrated circuits may then be separated from one another by dicing or sawing and then may be mounted into individual packages. In the more general case, the patterns on the substrate may be used to define artifacts such as display pixels, holograms, directed self-assembly (DSA) guard bands, or magnetic recording heads. Conventional optical lithography writing machines typically reduce the photomask pattern by a factor of four during the optical lithographic process. Therefore, patterns formed on the reticle or mask must be four times larger than the size of the desired pattern on the substrate or wafer.

In the production or manufacturing of semiconductor devices, such as integrated circuits, non-optical methods may be used to transfer a pattern on a lithographic mask to a substrate such as a silicon wafer. Nanoimprint lithography (NIL) is an example of a non-optical lithography process. In nanoimprint lithography, a lithographic mask pattern is transferred to a surface through contact of the lithography mask with the surface.

In the production or manufacturing of semiconductor devices, such as integrated circuits, maskless direct write may also be used to fabricate the semiconductor devices. Maskless direct write is a printing process in which charged particle beam lithography is used to transfer patterns to a substrate such as a semiconductor or silicon wafer to create the integrated circuit. Other substrates could include flat panel displays, imprint masks for nano-imprinting, or even reticles. Desired patterns of a layer are written directly on the surface, which in this case is also the substrate. Once the patterned layer is transferred the layer may undergo various other processes such as etching, ion-implantation (doping), metallization, oxidation, and polishing. These processes are employed to finish an individual layer in the substrate. If several layers are required, then the whole process or variations thereof will be repeated for each new layer. Some of the layers may be written using optical lithography while others may be written using maskless direct write to fabricate the same substrate. Also, some patterns of a given layer may be written using optical lithography, and other patterns written using maskless direct write. Eventually, a combination of multiples of devices or integrated circuits will be present on the substrate. These integrated circuits are then separated from one another by dicing or sawing and then mounted into individual packages. In the more general case, the patterns on the surface may be used to define artifacts such as display pixels, holograms, or magnetic recording heads.

Two common types of charged particle beam lithography are variable shaped beam (VSB) and character projection (CP). These are both sub-categories of shaped beam charged particle beam lithography, in which a precise electron beam is shaped and steered so as to expose a resist-coated surface, such as the surface of a wafer or the surface of a reticle. In VSB, these shapes are simple shapes, usually limited to rectangles of certain minimum and maximum sizes and with sides which are parallel to the axes of a Cartesian coordinate plane (i.e. of “Manhattan” orientation), and 45 degree right triangles (i.e. triangles with their three internal angles being 45 degrees, 45 degrees, and 90 degrees) of certain minimum and maximum sizes. At predetermined locations, doses of electrons are shot into the resist with these simple shapes. The total writing time for this type of system increases with the number of shots. In character projection (CP), there is a stencil in the system that has in it a variety of apertures or characters which may be complex shapes such as rectilinear, arbitrary-angled linear, circular, nearly circular, annular, nearly annular, oval, nearly oval, partially circular, partially nearly circular, partially annular, partially nearly annular, partially nearly oval, or arbitrary curvilinear shapes, and which may be a connected set of complex shapes or a group of disjointed sets of a connected set of complex shapes. An electron beam can be shot through a character on the stencil to efficiently produce more complex patterns on the reticle. In theory, such a system can be faster than a VSB system because it can shoot more complex shapes with each time-consuming shot. Thus, an E-shaped pattern shot with a VSB system takes four shots, but the same E-shaped pattern can be shot with one shot with a character projection system. Note that VSB systems can be thought of as a special (simple) case of character projection, where the characters are just simple characters, usually rectangles or 45-45-90 degree triangles. It is also possible to partially expose a character. This can be done by, for instance, blocking part of the particle beam. For example, the E-shaped pattern described above can be partially exposed as an F-shaped pattern or an I-shaped pattern, where different parts of the beam are cut off by an aperture. This is the same mechanism as how various sized rectangles can be shot using VSB. In this disclosure, partial projection is used to mean both character projection and VSB projection. Shaped beam charged particle beam lithography may use either a single shaped beam, or may use a plurality of shaped beams simultaneously exposing the surface, the plurality of shaped beams producing a higher writing speed than a single shaped beam.

As indicated, in lithography the lithographic mask or reticle comprises geometric patterns corresponding to the circuit components to be integrated onto a substrate. The patterns used to manufacture the reticle may be generated utilizing computer-aided design (CAD) software or programs. In designing the patterns the CAD program may follow a set of pre-determined design rules in order to create the reticle. These rules are set by processing, design, and end-use limitations. An example of an end-use limitation is defining the geometry of a transistor in a way in which it cannot sufficiently operate at the required supply voltage. In particular, design rules can define the space tolerance between circuit devices or interconnect lines. The design rules are, for example, used to ensure that the circuit devices or lines do not interact with one another in an undesirable manner. For example, the design rules are used so that lines do not get too close to each other in a way that may cause a short circuit. The design rule limitations reflect, among other things, the smallest dimensions that can be reliably fabricated. When referring to these small dimensions, one usually introduces the concept of a critical dimension. These are, for instance, defined as the smallest width of a line or the smallest space between two lines, those dimensions requiring exquisite control.

One goal in integrated circuit fabrication by optical lithography is to reproduce the original circuit design on the substrate by use of the reticle. Integrated circuit fabricators are always attempting to use the semiconductor wafer real estate as efficiently as possible. Engineers keep shrinking the size of the circuits to allow the integrated circuits to contain more circuit elements and to use less power. As the size of an integrated circuit critical dimension is reduced and its circuit density increases, the critical dimension of the circuit pattern or physical design approaches the resolution limit of the optical exposure tool used in conventional optical lithography. As the critical dimensions of the circuit pattern become smaller and approach the resolution value of the exposure tool, the accurate transcription of the physical design to the actual circuit pattern developed on the resist layer becomes difficult. To further the use of optical lithography to transfer patterns having features that are smaller than the light wavelength used in the optical lithography process, a process known as optical proximity correction (OPC) has been developed. OPC alters the physical design to compensate for distortions caused by effects such as optical diffraction and the optical interaction of features with proximate features. OPC includes all resolution enhancement technologies performed with a reticle.

OPC may add sub-resolution lithographic features to mask patterns to reduce differences between the original physical design pattern, that is, the design, and the final transferred circuit pattern on the substrate. The sub-resolution lithographic features interact with the original patterns in the physical design and with each other and compensate for proximity effects to improve the final transferred circuit pattern. One feature that is used to improve the transfer of the pattern is a sub-resolution assist feature (SRAF). Another feature that is added to improve pattern transference is referred to as “serifs”. Serifs are small features that can be positioned on an interior or exterior corner of a pattern to sharpen the corner in the final transferred image. It is often the case that the precision demanded of the surface manufacturing process for SRAFs is less than the precision demanded for patterns that are intended to print on the substrate, often referred to as main features. Serifs are a part of a main feature. As the limits of optical lithography are being extended far into the sub-wavelength regime, the OPC features must be made more and more complex in order to compensate for even more subtle interactions and effects. As imaging systems are pushed closer to their limits, the ability to produce reticles with sufficiently fine OPC features becomes critical. Although adding serifs or other OPC features to a mask pattern is advantageous, it also substantially increases the total feature count in the mask pattern. For example, adding a serif to each of the corners of a square using conventional techniques adds eight more rectangles to a mask or reticle pattern. Adding OPC features is a very laborious task, requires costly computation time, and results in more expensive reticles. Not only are OPC patterns complex, but since optical proximity effects are long range compared to minimum line and space dimensions, the correct OPC patterns in a given location depend significantly on what other geometry is in the neighborhood. Thus, for instance, a line end will have different size serifs depending on what is near it on the reticle. This is even though the objective might be to produce exactly the same shape on the wafer. These slight but critical variations are important and have prevented others from being able to form reticle patterns. It is conventional to discuss the OPC-decorated patterns to be written on a reticle in terms of main features, that is features that reflect the design before OPC decoration, and OPC features, where OPC features might include serifs, jogs, and SRAF. To quantify what is meant by slight variations, a typical slight variation in OPC decoration from neighborhood to neighborhood might be 5% to 80% of a main feature size. Note that for clarity, variations in the design of the OPC are what is being referenced. Manufacturing variations such as corner rounding will also be present in the actual surface patterns. When these OPC variations produce substantially the same patterns on the wafer, what is meant is that the geometry on the wafer is targeted to be the same within a specified error, which depends on the details of the function that that geometry is designed to perform, e.g., a transistor or a wire. Nevertheless, typical specifications are in the 2%-50% of a main feature range. There are numerous manufacturing factors that also cause variations, but the OPC component of that overall error is often in the range listed. OPC shapes such as sub-resolution assist features are subject to various design rules, such as a rule based on the size of the smallest feature that can be transferred to the wafer using optical lithography. Other design rules may come from the mask manufacturing process or, if a character projection charged particle beam writing system is used to form the pattern on a reticle, from the stencil manufacturing process. It should also be noted that the accuracy requirement of the SRAF features on the mask may be lower than the accuracy requirements for the main features on the mask. As process nodes continue to shrink, the size of the smallest SRAFs on a photomask also shrinks. For example, at the 20 nm logic process node, 40 nm to 60 nm SRAFs are needed on the mask for the highest precision layers.

Inverse lithography technology (ILT) is one type of OPC technique. ILT is a process in which a pattern to be formed on a reticle is directly computed from a pattern which is desired to be formed on a substrate such as a silicon wafer. This may include simulating the optical lithography process in the reverse direction, using the desired pattern on the substrate as input. ILT-computed reticle patterns may be purely curvilinear—i.e. completely non-rectilinear—and may include circular, nearly circular, annular, nearly annular, oval and/or nearly oval patterns. Since these ideal ILT curvilinear patterns are difficult and expensive to form on a reticle using conventional techniques, rectilinear approximations or rectilinearizations of the curvilinear patterns may be used. The rectilinear approximations decrease accuracy, however, compared to the ideal ILT curvilinear patterns. Additionally, if the rectilinear approximations are produced from the ideal ILT curvilinear patterns, the overall calculation time is increased compared to ideal ILT curvilinear patterns. In this disclosure ILT, OPC, source mask optimization (SMO), and computational lithography are terms that are used interchangeably.

EUV optical lithography has a much higher resolution than conventional optical lithography. The very high resolution of EUV significantly reduces the need for OPC processing, resulting in lower mask complexity for EUV than for 193 nm optical lithography. However, because of the very high resolution of EUV, imperfections in a photomask, such as excessive line edge roughness (LER), will be transferred to the wafer. Therefore, the accuracy requirements for EUV masks are higher than those for conventional optical lithography. Additionally, even though EUV mask shapes are not complicated by the addition of complex SRAFs or serifs required for conventional 193 nm lithography, EUV mask shapes are complicated by an addition of some complexities unique to EUV manufacturing. Of particular relevance in writing patterns on masks for EUV lithography is mid-range scattering of charged particles such as electrons, which may affect a radius of about 2 um. This mid-range scattering introduces a new consideration for mask data preparation, because for the first time the influence from neighboring patterns has significant impact on the shape that a particular pattern would cast onto the mask surface. Previously, when exposing masks for use with conventional 193 nm lithography, the short-range scattering affected only the pattern being written, and the long-range scattering had a large enough effective range that only the size of a pattern, and not its detailed shape, was affected, making it possible to make corrections by only using dose modulation. In addition, since EUV processing of wafers is more expensive, it is desirable to reduce or eliminate multiple patterning. Multiple patterning is used in conventional optical lithography to allow exposure of small features by exposing patterns for one layer of wafer processing using multiple masks, each of which contains a portion of the layer pattern. Reducing or eliminating multiple exposures requires the single mask to contain more fine patterns. For example, a series of collinear line segments may be double-patterned by first drawing a long line, then cutting the line into line segments by a second mask in conventional lithography. The same layer written with a single mask, such as for EUV lithography, would require a mask containing many smaller line segments. The need to write larger numbers of finer patterns on a single mask, each pattern needing to be more accurate, increases the need for precision on EUV masks.

There are a number of technologies used for forming patterns on a reticle, including using optical lithography or charged particle beam lithography. The most commonly used system is the variable shaped beam (VSB), where, as described above, doses of electrons with simple shapes such as Manhattan rectangles and 45-degree right triangles expose a resist-coated reticle surface. In conventional mask writing, the doses or shots of electrons are designed to avoid overlap wherever possible, so as to greatly simplify calculation of how the resist on the reticle will register the pattern. Similarly, the set of shots is designed so as to completely cover the pattern area that is to be formed on the reticle. U.S. Pat. No. 7,754,401 discloses a method of mask writing in which intentional shot overlap for writing patterns is used. When overlapping shots are used, charged particle beam simulation can be used to determine the pattern that the resist on the reticle will register. Use of overlapping shots may allow patterns to be written with reduced shot count or higher accuracy or both. U.S. Pat. No. 7,754,401 also discloses use of dose modulation, where the assigned dosages of shots vary with respect to the dosages of other shots. The term model-based fracturing is used to describe the process of determining shots using the techniques of U.S. Pat. No. 7,754,401.

Reticle writing for the most advanced technology nodes typically involves multiple passes of charged particle beam writing, a process called multi-pass exposure, whereby the given shape on the reticle is written and overwritten. Typically, two to four passes are used to write a reticle to average out precision errors in the charged particle beam writer, allowing the creation of more accurate photomasks. Also typically, the list of shots, including the dosages, is the same for every pass. In one variation of multi-pass exposure, the lists of shots may vary among exposure passes, but the union of the shots in any exposure pass covers the same area. Multi-pass writing can reduce over-heating of the resist coating the surface. Multi-pass writing also averages out random errors of the charged particle beam writer. Multi-pass writing using different shot lists for different exposure passes can also reduce the effects of certain systemic errors in the writing process.

Current optical lithography writing machines typically reduce the photomask pattern by a factor of four during the optical lithographic process. Therefore, patterns formed on a reticle or mask must be four times larger than the size of the desired pattern on the substrate or wafer.

Current-technology charged particle beam writers, using conventional techniques, can resolve features as small as 100 nm. For features smaller than 100 nm, however, conventional writing techniques may fail to accurately resolve features. Additionally, manufacturing variation may produce unacceptable LER and critical dimension (CD) variation. This can be a problem for both conventional optical lithography, where OPC may produce SRAF's having mask dimensions smaller than 100 nm, and for EUV lithography, where the main mask patterns may be smaller than 100 nm and where mask specifications may be tighter than for masks used for conventional optical lithography.

### SUMMARY OF THE DISCLOSURE

A method and system for fracturing or mask data preparation for charged particle beam lithography are disclosed in which a plurality of charged particle beam shots is determined that will form a pattern on a surface using a multi-beam charged particle beam writer, where the sensitivity of the pattern on the surface to manufacturing variation is reduced by increasing edge slope.

### BRIEF DESCRIPTION OF THE DRAWINGS

FIG. 1 illustrates an example of a charged particle beam system;

FIG. 2 illustrates an example of an electro-optical schematic diagram of a multi-beam exposure system;

FIG. 3A illustrates an example of a rectangular shot;

FIG. 3B illustrates an example of a circular character projection shot;

FIG. 3C illustrates an example of a trapezoidal shot;

FIG. 3D illustrates an example of a dragged shot;

FIG. 3E illustrates an example of a shot which is an array of circular patterns;

FIG. 3F illustrates an example of a shot which is a sparse array of rectangular patterns;

FIG. 4 illustrates an example of a multi-beam charged particle beam system;

FIG. 5A illustrates an example of a cross-sectional dosage graph, showing registered pattern widths for each of two resist thresholds;

FIG. 5B illustrates an example of a cross-sectional dosage graph similar to FIG. 5A, but with a higher dosage edge slope than in FIG. 5A;

FIG. 6A illustrates an example of a desired 100 nm line-end pattern to be formed on a reticle;

FIG. 6B illustrates an example of a simulated pattern formed using shots generated by fracturing the pattern of FIG. 6A using conventional techniques;

FIG. 7A illustrates an example of a desired 80 nm line-end pattern to be formed on a reticle;

FIG. 7B illustrates an example of a simulated pattern formed using shots generated by fracturing the pattern of FIG. 7A using conventional techniques;

FIG. 8A illustrates an example of a desired 60 nm line-end pattern to be formed on a reticle;

FIG. 8B illustrates an example of a simulated pattern formed using shots generated by fracturing the pattern of FIG. 8A using conventional techniques;

FIG. 9 illustrates various examples of groups of shots that may be used to form a 80 nm line-end pattern;

FIG. 10 illustrates simulated patterns formed by the various shot groups of FIG. 9;

FIG. 11A illustrates an example of a group of rectangular patterns to be formed on a surface;

FIG. 11B illustrates an example of how the patterns of FIG. 11A may be formed on a surface using conventional non-overlapping VSB shots, in the presence of mid-range scattering;

FIG. 12A illustrates an example of a set of overlapping VSB shots that may be used to form the patterns of FIG. 11A on a surface;

FIG. 12B illustrates an example of a pattern that may be formed on a surface from the shots of FIG. 12A;

FIG. 13A illustrates an example of a contact or via pattern;

FIG. 13B illustrates dosages to expose the contact or via pattern of FIG. 13A conventionally, for a first of two exposure passes using a multi-beam exposure system;

FIG. 13C illustrates dosages to expose the contact or via pattern of FIG. 13A conventionally, for a second of two exposure passes using a multi-beam exposure system;

FIG. 13D illustrates the combined dosages from FIG. 13B pass 1 and FIG. 13C pass 2 for conventional exposure of the contact or via pattern using a multi-beam exposure system;

FIG. 13E illustrates example dosages to expose the contact or via pattern of FIG. 13A using an exemplary method, for a first of two exposure passes using a multi-beam exposure system;

FIG. 13F illustrates example dosages to expose the contact or via pattern of FIG. 13A using an exemplary method, for a second of two exposure passes using a multi-beam exposure system;

FIG. 13G illustrates the combined dosages from FIG. 13E pass 1 and FIG. 13F pass 2 for exemplary exposure of the contact or via pattern using a multi-beam exposure system;

FIG. 13H illustrates example dosages to expose the contact or via pattern of FIG. 13A using an exemplary method, for a first of two exposure passes using a multi-beam exposure system, using different dosages than the example of FIG. 13E;

FIG. 13I illustrates example dosages to expose the contact or via pattern of FIG. 13A using an exemplary method, for a second of two exposure passes using a multi-beam exposure system, using different dosages than the example of FIG. 13F;

FIG. 13J illustrates the combined dosages from FIG. 13H pass 1 and FIG. 13I pass 2 for exemplary exposure of the contact or via pattern using a multi-beam exposure system;

FIG. 14 illustrates a conceptual flow diagram of how to prepare a surface, such as a reticle, for use in fabricating a substrate such as an integrated circuit on a silicon wafer using optical lithography;

FIG. 15A illustrates a conceptual flow diagram of one method of combining model-based and conventional fracturing in the same design; and

FIG. 15B illustrates a conceptual flow diagram of another method of combining model-based and conventional fracturing in the same design.

### DETAILED DESCRIPTION OF THE EMBODIMENTS

The present disclosure describes a method for enhancing the accuracy of charged particle beam exposure by use of overlapping shots. The present invention enhances the ability of charged particle beam systems to accurately produce patterns smaller than 100 nm on a reticle, with acceptable CD variation and LER in light of manufacturing variation. Additionally, the present invention expands the process window of manufacturing variations under which these accurate patterns may be produced.

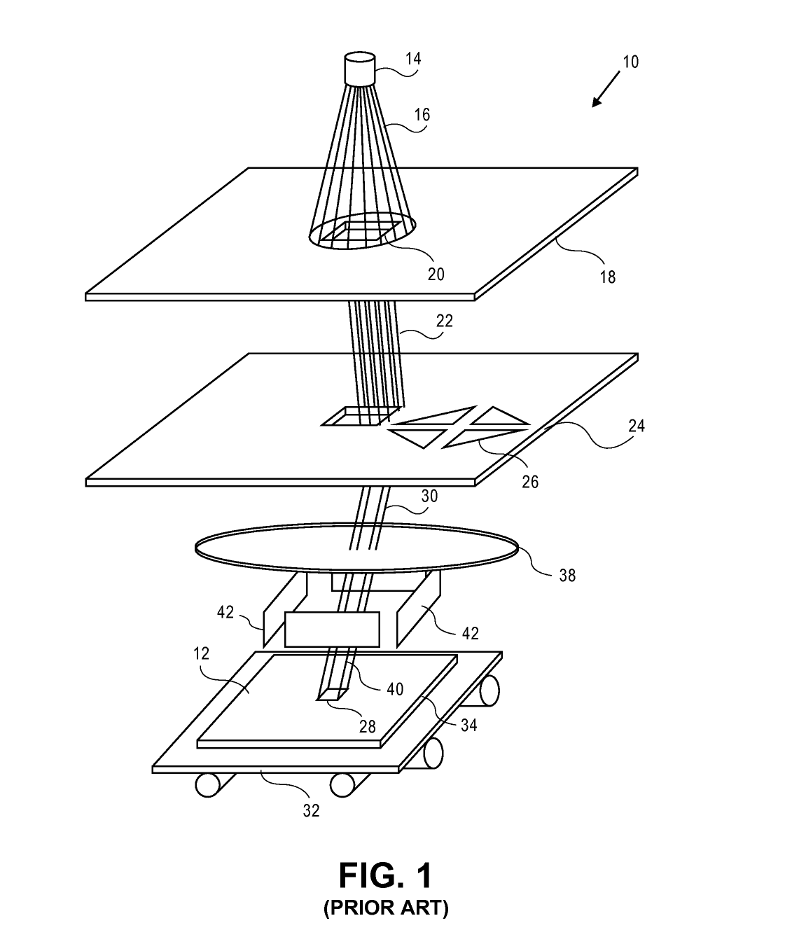

Referring now to the drawings, wherein like numbers refer to like items, FIG. 1 illustrates an embodiment of a lithography system, such as a charged particle beam writer system, in this case an electron beam writer system 10, that employs a variable shaped beam (VSB) to manufacture a surface 12. The electron beam writer system 10 has an electron beam source 14 that projects an electron beam 16 toward an aperture plate 18. The plate 18 has an aperture 20 formed therein which allows the electron beam 16 to pass. Once the electron beam 16 passes through the aperture 20 it is directed or deflected by a system of lenses (not shown) as electron beam 22 toward another rectangular aperture plate or stencil mask 24. The stencil 24 has formed therein a number of openings or apertures 26 that define various simple shapes such as rectangles and triangles. Each aperture 26 formed in the stencil 24 may be used to form a pattern in the surface 12 of a substrate 34, such as a silicon wafer, a reticle or other substrate. An electron beam 30 emerges from one of the apertures 26 and passes through an electromagnetic or electrostatic reduction lens 38, which reduces the size of the pattern emerging from the aperture 26. In commonly available charged particle beam writer systems, the reduction factor is between 10 and 60. The reduced electron beam 40 emerges from the reduction lens 38 and is directed by a series of deflectors 42 onto the surface 12 as a pattern 28. The surface 12 is coated with resist (not shown) which reacts with the electron beam 40. The electron beam 22 may be directed to overlap a variable portion of an aperture 26, affecting the size and shape of the pattern 28. Blanking plates (not shown) are used to deflect the beam 16 or the shaped beam 22 so to prevent the electron beam from reaching the surface 12 during a period after each shot when the lenses directing the beam 22 and the deflectors 42 are being re-adjusted for the succeeding shot. Typically the blanking plates are positioned so as to deflect the electron beam 16 to prevent it from illuminating aperture 20. Conventionally, the blanking period may be a fixed length of time, or it may vary depending, for example, on how much the deflector 42 must be re-adjusted for the position of the succeeding shot.

In electron beam writer system 10, the substrate 34 is mounted on a movable platform or stage 32. The stage 32 allows substrate 34 to be repositioned so that patterns which are larger than the maximum deflection capability or field size of the charged particle beam 40 may be written to surface 12 in a series of subfields, where each subfield is within the capability of deflector 42 to deflect the beam 40. In one embodiment the substrate 34 may be a reticle. In this embodiment, the reticle, after being exposed with the pattern, undergoes various manufacturing steps through which it becomes a lithographic mask or photomask. The mask may then be used in an optical lithography machine to project an image of the reticle pattern 28, generally reduced in size, onto a silicon wafer to produce an integrated circuit. More generally, the mask is used in another device or machine to transfer the pattern 28 on to a substrate (not illustrated).

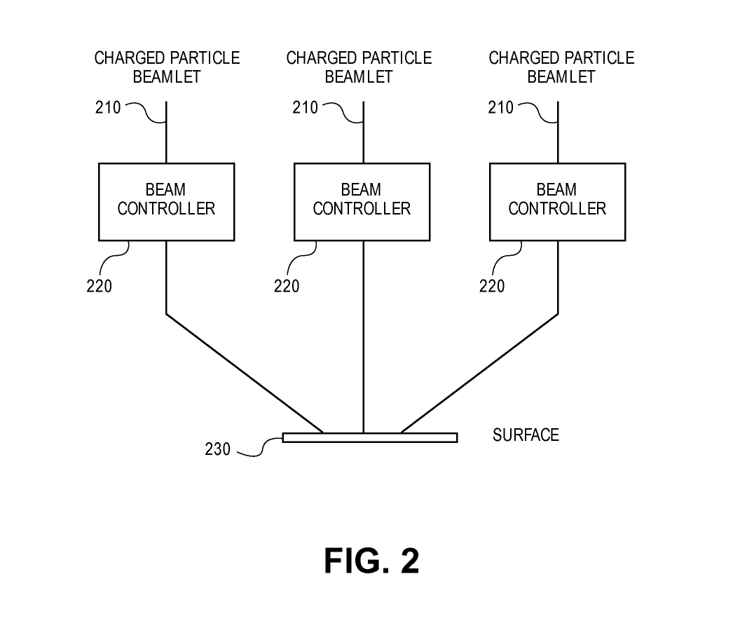

A charged particle beam system may expose a surface with a plurality of individually-controllable beams or beamlets. FIG. 2 illustrates an electro-optical schematic diagram in which there are three charged particle beamlets 210. Associated with each beamlet 210 is a beam controller 220. Each beam controller 220 can, for example, allow its associated beamlet 210 to strike surface 230, and can also prevent beamlet 210 from striking the surface 230. In some embodiments, beam controller 220 may also control beam blur, magnification, size and/or shape of beamlet 210. In this disclosure, a charged particle beam system which has a plurality of individually-controllable beamlets is called a multi-beam system. In some embodiments, charged particles from a single source may be sub-divided to form a plurality of beamlets 210. In other embodiments a plurality of sources may be used to create the plurality of beamlets 210. In some embodiments, beamlets 210 may be shaped by one or more apertures, whereas in other embodiments there may be no apertures to shape the beamlets. Each beam controller 220 may allow the period of exposure of its associated beamlet to be controlled individually. Generally the beamlets will be reduced in size by one or more lenses (not shown) before striking the surface 230, which will typically be coated with a resist. In some embodiments each beamlet may have a separate electro-optical lens, while in other embodiments a plurality of beamlets, including possibly all beamlets, will share an electro-optical lens.

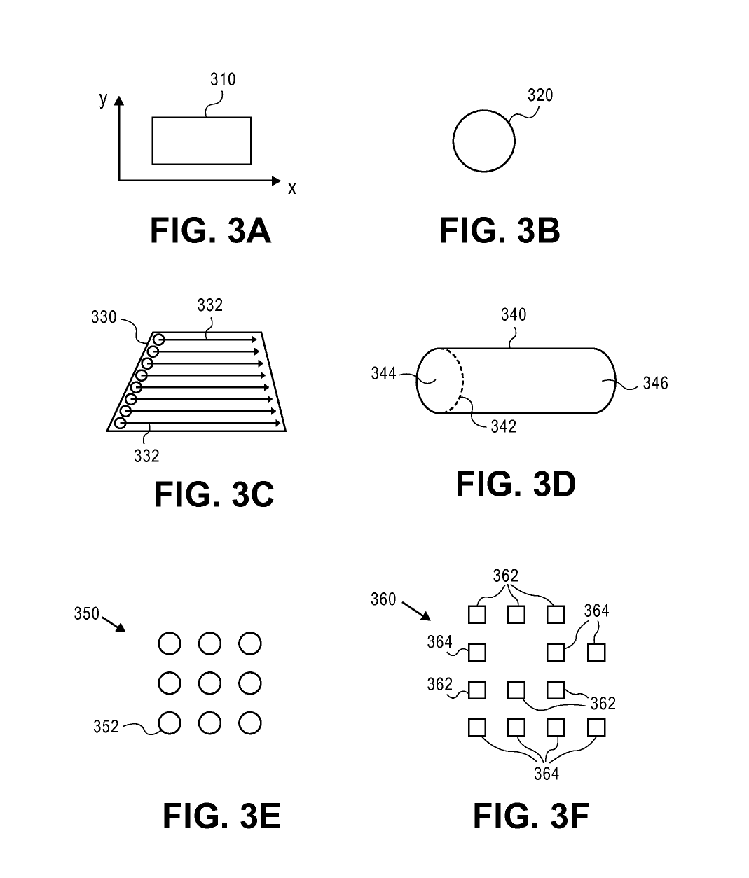

For purposes of this disclosure, a shot is the exposure of some surface area over a period of time. The area may be comprised of multiple discontinuous smaller areas. A shot may be comprised of a plurality of other shots which may or may not overlap, and which may or may not be exposed simultaneously. A shot may comprise a specified dose, or the dose may be unspecified. Shots may use a shaped beam, an unshaped beam, or a combination of shaped and unshaped beams. FIG. 3 illustrates some various types of shots. FIG. 3A illustrates an example of a rectangular shot 310. A VSB charged particle beam system can, for example, form rectangular shots in a variety of x and y dimensions. FIG. 3B illustrates an example of a character projection (CP) shot 320, which is circular in this example. FIG. 3C illustrates an example of a trapezoidal shot 330. In one embodiment, shot 330 may be a created using a raster-scanned charged particle beam, where the beam is scanned, for example, in the x-direction as illustrated with scan lines 332. FIG. 3D illustrates an example of a dragged shot 340, disclosed in U.S. Patent Application Publication 2011-0089345. Shot 340 is formed by exposing the surface with a curvilinear shaped beam 342 at an initial reference position 344, and then moving the shaped beam across the surface from position 344 to position 346. A dragged shot path may be, for example, linear, piecewise linear, or curvilinear.

FIG. 3E illustrates an example of a shot 350 that is an array of circular patterns 352. Shot 350 may be formed in a variety of ways, including multiple shots of a single circular CP character, one or more shots of a CP character which is an array of circular apertures, and one or more multi-beam shots using circular apertures. FIG. 3F illustrates an example of a shot 360 that is a sparse array of rectangular patterns 362 and 364. Shot 360 may be formed in a variety of ways, including a plurality of VSB shots, a CP shot, and one or more multi-beam shots using rectangular apertures. In some embodiments of multi-beam, shot 360 may comprise a plurality of interleaved groups of other multi-beam shots. For example, patterns 362 may be shot simultaneously, then patterns 364 may be shot simultaneously at a time different from patterns 362.

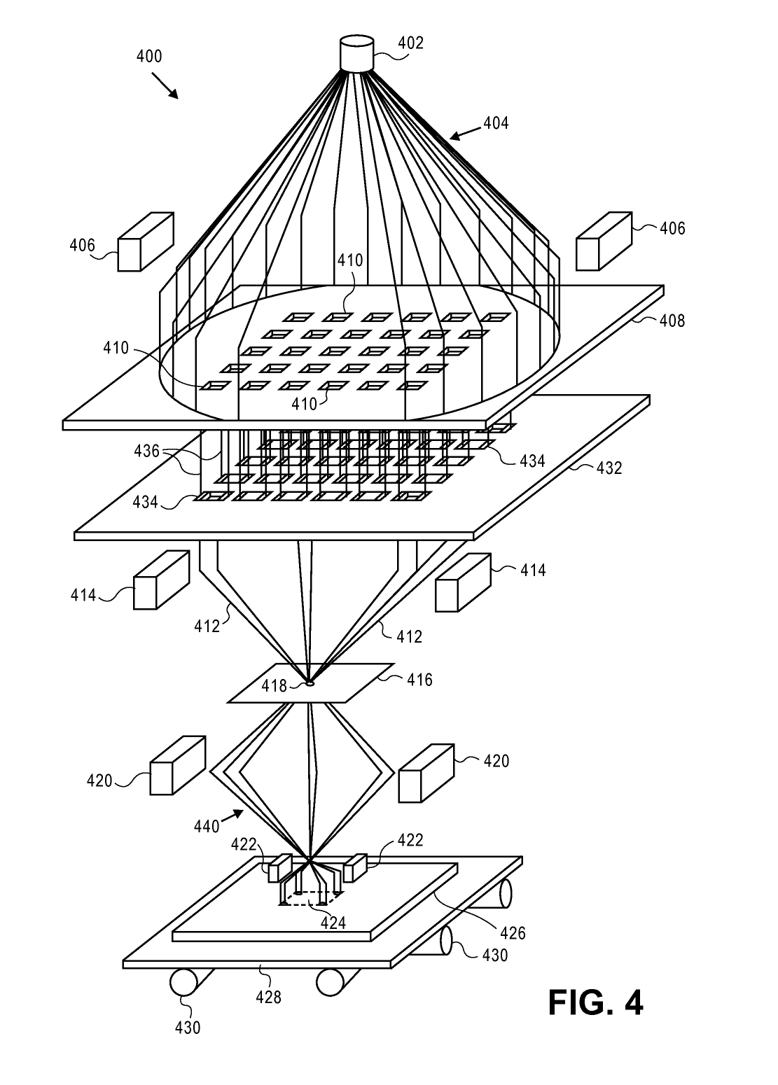

FIG. 4 illustrates an embodiment of a charged particle beam exposure system 400. Charged particle beam system 400 is a multi-beam system, in which a plurality of individually-controllable shaped beams can simultaneously expose a surface. Multi-beam system 400 has an electron beam source 402 that creates an electron beam 404. The electron beam 404 is directed toward aperture plate 408 by condenser 406, which may include electrostatic and/or magnetic elements. Aperture plate 408 has a plurality of apertures 410 which are illuminated by electron beam 404, and through which electron beam 404 passes to form a plurality of shaped beamlets 436. In some embodiments, aperture plate 408 may have hundreds or thousands of apertures 410. Although FIG. 4 illustrates an embodiment with a single electron beam source 402, in other embodiments apertures 410 may be illuminated by electrons from a plurality of electron beam sources. Apertures 410 may be rectangular, or may be of a different shape, for example circular. The set of beamlets 436 then illuminates a blanking controller plate 432. The blanking controller plate 432 has a plurality of blanking controllers 434, each of which is aligned with a beamlet 436. Each blanking controller 434 can individually control its associated beamlet 436, so as to either allow the beamlet 436 to strike surface 424, or to prevent the beamlet 436 from striking the surface 424. The amount of time for which the beam strikes the surface controls the total energy or “dose” applied by that beamlet. Therefore, the dose of each beamlet may be independently controlled.

In FIG. 4 beamlets that are allowed to strike surface 424 are illustrated as beamlets 412. In one embodiment, the blanking controller 434 prevents its beamlet 436 from striking the surface 424 by deflecting beamlet 436 so that it is stopped by an aperture plate 416 which contains an aperture 418. In some embodiments, blanking plate 432 may be directly adjacent to aperture plate 408. In other embodiments, the relative locations of aperture plate 408 and blanking controller 432 may be reversed from the position illustrated in FIG. 4, so that beam 404 strikes the plurality of blanking controllers 434. A system of lenses comprising elements 414, 420, and 422 allows projection of the plurality of beamlets 412 onto surface 424 of substrate 426, typically at a reduced size compared to the plurality of apertures 410. The reduced-size beamlets form a beamlet group 440 which strikes the surface 424 to form a pattern that matches a pattern of a subset of apertures 410, the subset being those apertures 410 for which corresponding blanking controllers 434 allow beamlets 436 to strike surface 424. In FIG. 4, beamlet group 440 has four beamlets illustrated for forming a pattern on surface 424.

Substrate 426 is positioned on movable platform or stage 428, which can be repositioned using actuators 430. By moving stage 428, beam 440 can expose an area larger than the dimensions of the maximum size pattern formed by beamlet group 440, using a plurality of exposures or shots. In some embodiments, the stage 428 remains stationary during an exposure, and is then repositioned for a subsequent exposure. In other embodiments, stage 428 moves continuously and at a variable velocity. In yet other embodiments, stage 428 moves continuously but at a constant velocity, which can increase the accuracy of the stage positioning. For those embodiments in which stage 428 moves continuously, a set of deflectors (not shown) may be used to move the beam to match the direction and velocity of stage 428, allowing the beamlet group 440 to remain stationary with respect to surface 424 during an exposure. In still other embodiments of multi-beam systems, individual beamlets in a beamlet group may be deflected across surface 424 independently from other beamlets in the beamlet group.

Other types of multi-beam systems may create a plurality of unshaped beamlets 436, such as by using a plurality of charged particle beam sources to create an array of Gaussian beamlets.

Referring again for FIG. 1, the minimum size pattern that can be projected with reasonable accuracy onto a surface 12 is limited by a variety of short-range physical effects associated with the electron beam writer system 10 and with the surface 12, which normally comprises a resist coating on the substrate 34. These effects include forward scattering, Coulomb effect, and resist diffusion. Beam blur, also called β_{f}, is a term used to include all of these short-range effects. The most modern electron beam writer systems can achieve an effective beam blur radius or β_{f} in the range of 20 nm to 30 nm. Forward scattering may constitute one quarter to one half of the total beam blur. Modern electron beam writer systems contain numerous mechanisms to reduce each of the constituent pieces of beam blur to a minimum. Since some components of beam blur are a function of the calibration level of a particle beam writer, the β_{f} of two particle beam writers of the same design may differ. The diffusion characteristics of resists may also vary. Variation of β_{f} based on shot size or shot dose can be simulated and systemically accounted for. But there are other effects that cannot or are not accounted for, and they appear as random variation.

The shot dosage of a charged particle beam writer such as an electron beam writer system is a function of the intensity of the beam source 14 and the exposure time for each shot. Typically the beam intensity remains fixed, and the exposure time is varied to obtain variable shot dosages. Different areas in a shot may have different exposure times, such as in a multi-beam shot. The exposure time may be varied to compensate for various long-range effects such as backscatter, fogging, and loading effects in a process called proximity effect correction (PEC). Electron beam writer systems usually allow setting an overall dosage, called a base dosage, which affects all shots in an exposure pass. Some electron beam writer systems perform dosage compensation calculations within the electron beam writer system itself, and do not allow the dosage of each shot to be assigned individually as part of the input shot list, the input shots therefore having unassigned shot dosages. In such electron beam writer systems all shots have the base dosage, before PEC. Other electron beam writer systems do allow dosage assignment on a shot-by-shot basis. In electron beam writer systems that allow shot-by-shot dosage assignment, the number of available dosage levels may be 64 to 4096 or more, or there may be a relatively few available dosage levels, such as 3 to 8 levels.

The mechanisms within electron beam writers have a relatively coarse resolution for calculations. As such, mid-range corrections such as may be required for EUV masks in the range of 2 μm cannot be computed accurately by current electron beam writers.

Conventionally, shots are designed so as to completely cover an input pattern with rectangular shots, while avoiding shot overlap wherever possible. Also, all shots are designed to have a normal dosage, which is a dosage at which a relatively large rectangular shot, in the absence of long-range effects, will produce a pattern on the surface which is the same size as is the shot size.

In exposing, for example, a repeated pattern on a surface using charged particle beam lithography, the size of each pattern instance, as measured on the final manufactured surface, will be slightly different, due to manufacturing variations. The amount of the size variation is an essential manufacturing optimization criterion. In current mask masking, a root mean square (RMS) variation of no more than 1 nm (1 sigma) in pattern size may be desired. More size variation translates to more variation in circuit performance, leading to higher design margins being required, making it increasingly difficult to design faster, lower-power integrated circuits. This variation is referred to as critical dimension (CD) variation. A low CD variation is desirable, and indicates that manufacturing variations will produce relatively small size variations on the final manufactured surface. In the smaller scale, the effects of a high CD variation may be observed as line edge roughness (LER). LER is caused by each part of a line edge being slightly differently manufactured, leading to some waviness in a line that is intended to have a straight edge. CD variation is, among other things, inversely related to the slope of the dosage curve at the resist threshold, which is called edge slope. Therefore, edge slope, or dose margin, is a critical optimization factor for particle beam writing of surfaces. In this disclosure, edge slope and dose margin are terms that are used interchangeably.

With conventional fracturing, without shot overlap, gaps or dose modulation, the dose margin of the written shapes is considered immutable: that is, there is no opportunity to improve dose margin by a choice of fracturing options. In modern practice, the avoidance of very narrow shots called slivers is an example of a practical rule-based method that helps to optimize the shot list for dose margin.

In a fracturing environment where overlapping shots and dose-modulated shots can be generated, there is both a need and an opportunity to optimize for dose margin. The additional flexibility in shot combinations allowed by use of shot overlap and dose modulation allows generation of fracturing solutions that appear to generate the target mask shapes on the surface, but may do so only under perfect manufacturing conditions. The use of overlapping shots and dose-modulated shots therefore creates incentive to address the issue of dose margin and its improvement.

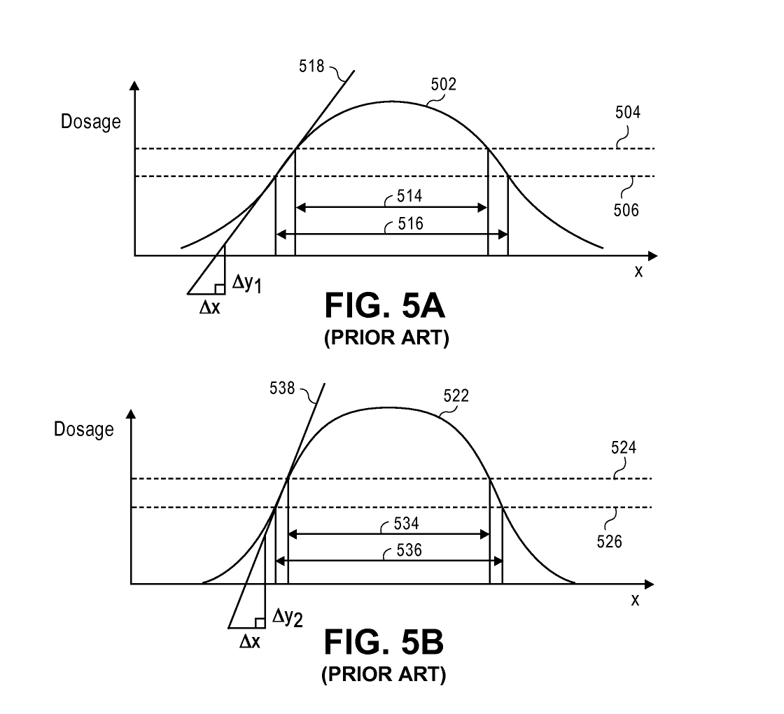

FIGS. 5A-B illustrate how critical dimension variation can be reduced by exposing the pattern on the resist so as to produce a relatively high edge slope in the exposure or dosage curve. FIG. 5A illustrates a cross-sectional dosage curve 502, where the x-axis shows the cross-sectional distance through an exposed pattern—such as the distance perpendicular to two of the pattern's edges—and the y-axis shows the dosage received by the resist. A pattern is registered by the resist where the received dosage is higher than a threshold. Two thresholds are illustrated in FIG. 5A, illustrating the effect of a variation in resist sensitivity. The higher threshold 504 causes a pattern of width 514 to be registered by the resist. The lower threshold 506 causes a pattern of width 516 to be registered by the resist, where width 516 is greater than width 514. Also illustrated in FIG. 5A is line segment 518 which is tangent to dosage curve 502 at the intersection of dosage curve 502 and resist threshold 506. The slope m₁ of line segment 518 is Δy₁/Δx, which is also the edge slope of dosage curve 502 at resist threshold 506. FIG. 5B illustrates another cross-sectional dosage curve 522. Two thresholds are illustrated, where threshold 524 is the same as threshold 504 of FIG. 5A, and threshold 526 is the same as threshold 506 of FIG. 5A. Also illustrated in FIG. 5B is line segment 538 which is tangent to dosage curve 522 at the intersection of dosage curve 522 and dosage 526. The slope m₂ of line segment 538 is Δy₂/Δx, which is also the edge slope of dosage curve 522 at resist threshold 526. As can be seen, the edge slope m₂ of dosage curve 522 at threshold 526 is greater than the edge slope m₁ of dosage curve 502 at threshold 506. For dosage curve 522, the higher threshold 524 causes a pattern of width 534 to be registered by the resist. The lower threshold 526 causes a pattern of width 536 to be registered by the resist. As can be seen, the difference between width 536 and width 534 is less than the difference between width 516 and width 514, due to the higher edge slope of dosage curve 522 compared to dosage curve 502. If the resist-coated surface is a reticle, then the lower sensitivity of curve 522 to variation in resist threshold can cause the pattern width on a photomask manufactured from the reticle to be closer to the target pattern width for the photomask, thereby increasing the yield of usable integrated circuits when the photomask is used to transfer a pattern to a substrate such as a silicon wafer. Similar improvement in tolerance to variation in dose for each shot is observed for dose curves with higher edge slopes. Achieving a relatively higher edge slope such as edge slope m₂ of dosage curve 522 at threshold 526 is therefore desirable.

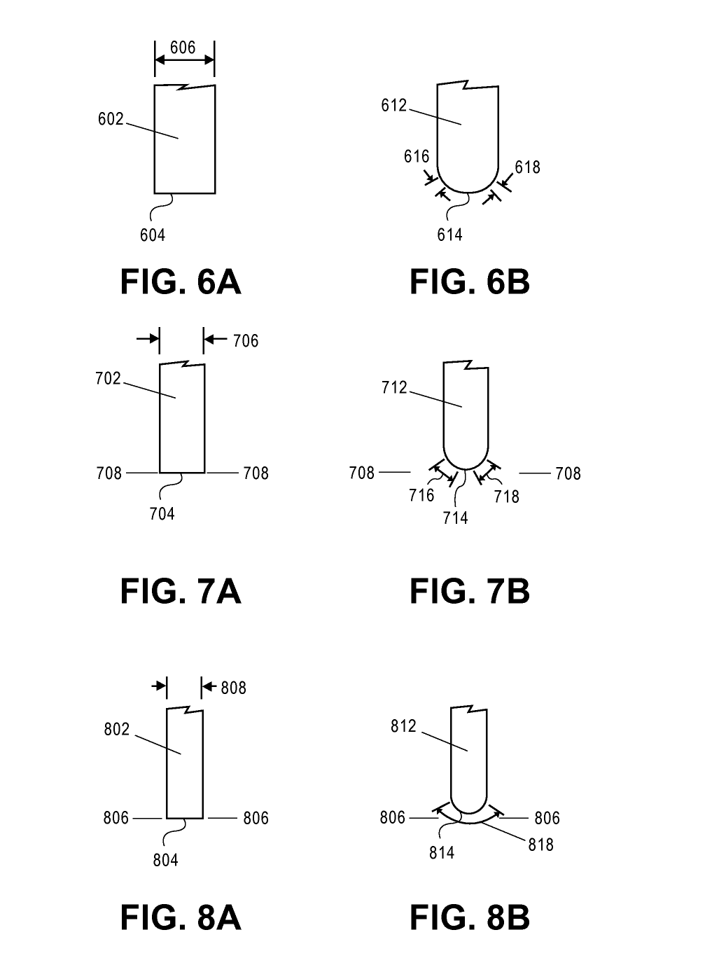

FIG. 6A illustrates an example of a designed pattern 602. Pattern 602 is designed to have a constant width 606, the width being 100 nm. Pattern 602 comprises a line-end 604. FIG. 6B illustrates an example of a simulated pattern 612 that may be formed on a surface using a conventional VSB shot, where the VSB shot is a 100 nm wide rectangle, and of a normal dosage. As can be seen in FIG. 6B, the line-end portion 614 of pattern 612 has rounded corners, due to beam blur caused by the physical limitations of the charged particle beam writer. Additionally, the exposed pattern has a poor edge slope in sections 616 and 618 of the pattern perimeter. This edge slope may be determined, for example, using particle beam simulation. The portions 616 and 618 of the pattern 612 may cause an undesirably-large variation in size due to manufacturing variation. The line-end 614, in its center section, however, is the desired length—i.e. having the same y-coordinate as the designed line-end 604.

FIG. 7A illustrates an example of a designed pattern 702. Pattern 702 is designed to have a constant width 706 of 80 nm. Pattern 702 comprises a line-end 704, where the y-coordinate of the line-end 704 is shown by reference line 708. FIG. 7B illustrates an example of a simulated pattern 712 that may be formed on a surface using a conventional VSB shot, where the VSB shot is 80 nm wide, and of a normal dosage. As with pattern 612, the line-end portion 714 of pattern 712 has rounded corners due to beam blur. Also, the portions 716 and 718 of the perimeter of pattern 712 have poor edge slope. As can be seen, the portions 716 and 718 of the perimeter of pattern 712 having poor edge slope are larger than the portions 616 and 618 of pattern 612 which have poor edge slope. This is due to the narrower 80 nm width of pattern 702 compared to the 100 nm width of pattern 602. Additionally, the y-coordinate of formed line-end 714 is larger than the y-coordinate of the reference line 708, meaning that pattern 712 has line-end shortening, which can affect the performance and/or functionality of an integrated circuit fabricated using a mask containing pattern 712.

FIG. 8A illustrates an example of a designed pattern 802. Pattern 802 is designed to have a constant width 808 of 60 nm. Pattern 802 comprises a line-end 804, where the y-coordinate of line-end 804 is shown by reference line 806. FIG. 8B illustrates an example of a pattern 812 that may be formed on a surface using a conventional VSB shot, where the VSB shot is 60 nm wide, and of a normal dosage. As can be seen, the line-end portion 814 of pattern 812 is very rounded. There is also line-end shortening—the minimum y-coordinate of pattern 812 is greater than the y-coordinate of reference line 806. Additionally, the perimeter region 818 of pattern 812 has a poor edge slope, affecting the entire line-end 814.

The patterns of FIGS. 6B, 7B and 8B illustrate how formation of patterns of 80 nm width and below may have line-end shortening, and may also have rounded corners with poor edge slope, when formed with conventional VSB shots.

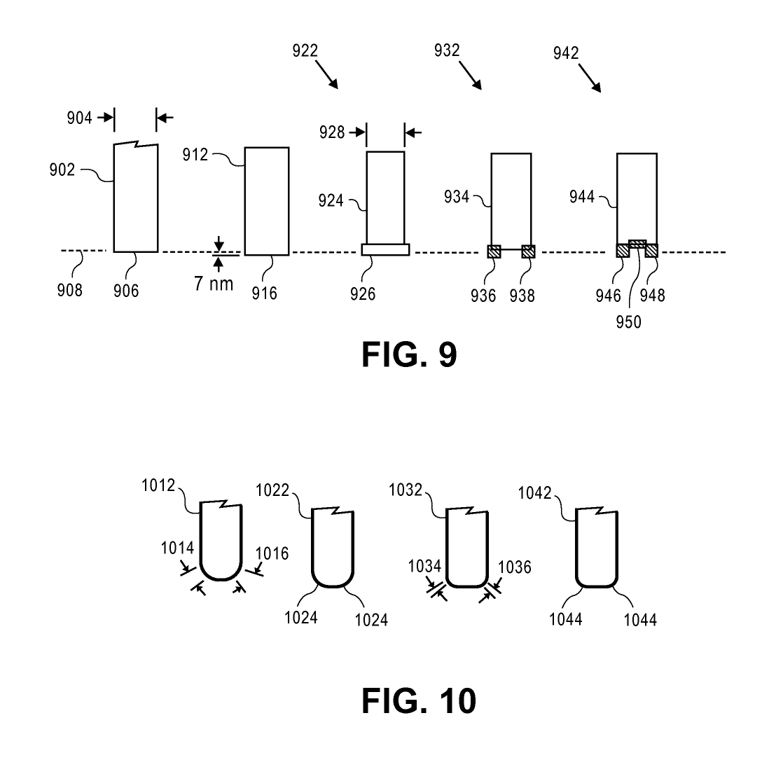

FIG. 9 illustrates various methods of fracturing a pattern to enhance the quality of the pattern formed on a surface such as a reticle. Shape 902 illustrates a designed line-end pattern, the pattern 902 having a width 904 of 80 nm. The pattern 902 comprises a line-end 906. Dashed line 908 denotes the y-coordinate of line-end 906. FIG. 9 pattern 912 illustrates one prior art method of fracturing pattern 902 to improve the quality of the formed pattern on a surface, compared with FIG. 7B pattern 712. Pattern 912 illustrates a single VSB shot, where the shot size has been expanded in the negative y-dimension, so that the minimum y-coordinate of the shot is 7 nm less than reference y-coordinate 908. The dose of shot 912 is a normal dose. FIG. 10 pattern 1012 illustrates a simulated shape of the shot 912. The line end of pattern 1012 has rounded corners, and also has perimeter regions 1014 and 1016 in which the edge slope of the pattern is too low.

FIG. 9 also illustrates three groups of VSB shots, group 922, group 932 and group 942, which can form the pattern 902. Shot group 932 and shot group 942 exemplify one embodiment of the current invention while shot group 922 represents a prior art method. Shot group 922 consists of shot 924 and shot 926, which do not overlap each other. Shot 924 is shot at 1.2 times a normal dose, before long-range PEC, and shot 926 is shot at a normal dose. The width 928 of shot 924 is less than 904, and is calculated so as to produce a pattern of width 904 on the surface with the larger-than-normal dosage. Shot 926, as can be seen, is extended in the negative and positive x-directions beyond the dimensions of shot 924 and also beyond the dimensions of pattern 902. FIG. 10 pattern 1022 illustrates the simulated pattern produced by shot group 922. The line-end corners 1024 of pattern 1022 have a higher edge slope than pattern 1012, with no part of the corner having a too-small edge slope. Additionally, though not illustrated, the higher-than-normal dose of shot 924 improves the edge slope on the left and right sides of pattern 1022 compared to pattern 1012. One method of determining the shots of shot group 922 is through model-based fracturing, which is the use of simulation, such as charged particle beam simulation, to determine a set of shots which can form a desired pattern on a resist-coated surface, by determining through simulation the pattern which will be produced on the surface from a given set of one or more shots, where some or all of the shots may have non-normal dosages. Alternatively, the shots of shot group 922 may be determined through rule-based methods. Model-based fracturing, although relatively more compute-intensive than rule-based fracturing, may determine a shot list that will produce a more accurate pattern on the surface, compared to a shot list determined using rule-based methods.

FIG. 9 shot group 932 illustrates an exemplary method of fracturing pattern 902 according to one embodiment of the current invention. Shot group 932 consists of shot 934, shot 936 and shot 938. Shots 936 and 938 are illustrated with shading for improved clarity. Shot 934 is shot at a higher-than-normal dose, for example 1.2 times normal dose, and the width of shot 934 is calculated so as to produce a pattern of width 904 on a surface. Shot 936 and shot 938 both overlap shot 934, and both extend below reference y-coordinate 908. The overlap between, for example, shot 934 and 936 is a partial overlap, meaning that the area of intersection between shot 934 and shot 936 is different than either shot. Shot 936 and shot 938 are shot at a normal dose in this example. FIG. 10 pattern 1032 illustrates a simulated pattern from shot group 932. Compared to pattern 1022, pattern 1032 exhibits less corner rounding, but also has worse edge slope on the corners, with the edge slope being less than the minimum acceptable value in perimeter regions 1034 and 1036. Shot group 932 illustrates how use of overlapping shots and other-than-normal dosages may allow patterns to be formed with higher-fidelity than using conventional non-overlapping shots with normal dosages.

FIG. 9 shot group 942 illustrates another example for fracturing pattern 902 according to the current invention, using partially overlapping shots. Shot group 942 consists of shots 944, 946, 948 and 950. Shots 946, 948 and 950 are illustrated with shading for improved clarity. Like shots 924 and 934, shot 944 uses a higher-than-normal dose such as of 1.2× normal. Shots 946, 948 and 950 use a normal dose in this example. Shot 950 overlaps shot 944. Shots 946 and 948 extend beyond reference y-coordinate 908. FIG. 10 pattern 1042 illustrates a simulated pattern from shot group 942. The corners 1044 of the pattern 1042 line-end are less rounded than, for example, the corers of pattern 1022. Additionally, the edge slope in the corner region is higher-than-minimum at all locations. Like shot group 932, shot group 942 illustrates how use of overlapping shots combined with other-than-normal dosages may allow patterns to be formed with higher-fidelity than with conventional methods or prior art methods such as illustrated with the method of shot 912.

The solution described above and illustrated in FIG. 9 shot groups 932 and 942 may be implemented even using a charged particle beam system that does not allow dosage assignment for individual shots. In one embodiment of the present invention, a small number of dosages may be selected, for example two dosages such as 1.0× normal and 1.2× normal, and shots for each of these two dosages may be separated and exposed in two separate exposure passes, where the base dosage for one exposure pass is 1.0× normal and the base dosage for the other exposure pass is 1.2× normal. For example, in FIG. 9 shot group 932, shot 936 and shot 938 may be assigned to a first exposure pass using a base dosage of 1.0× normal dosage, and shot 934 may be assigned to a second exposure pass using a base dosages of 1.2× normal dosage. In this embodiment, the union of shots for any exposure pass will be different than the union of shots for all of the exposure passes combined.

In other embodiments of the current invention, sensitivity to types of manufacturing variation other than dosage variation may be reduced by using overlapping shots. Beam blur variation is an example of another type of manufacturing variation. Additionally, the methods of the current invention may also be practiced using complex character projection (CP) shots, or with a combination of complex CP and VSB shots.

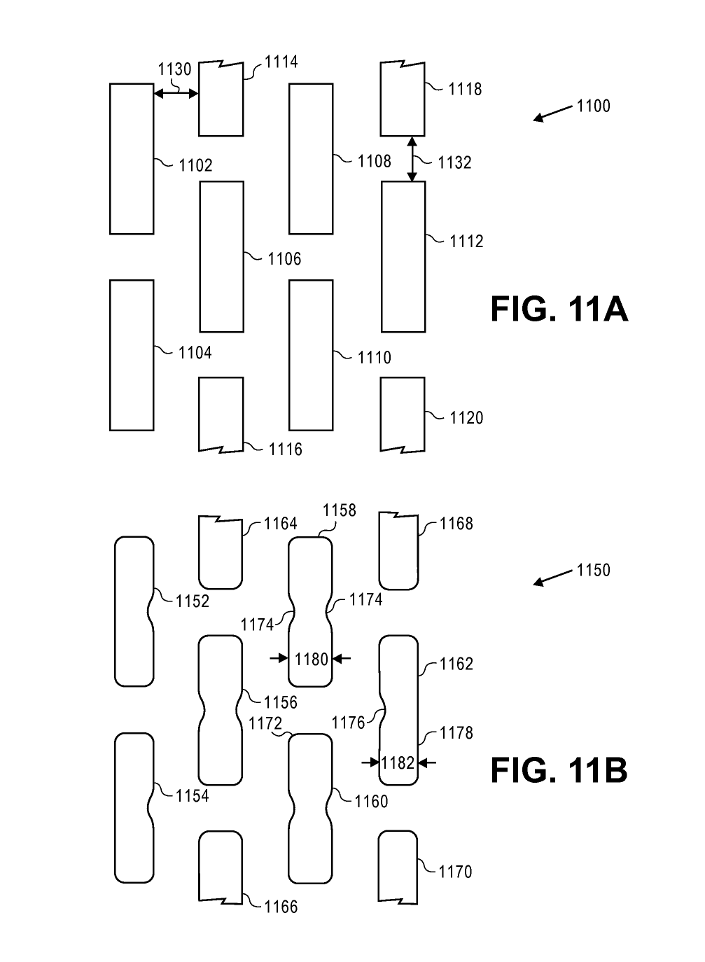

FIG. 11A illustrates an example of a group of rectangular patterns 1100 to be formed on a surface. The group of patterns 1100 comprises six complete rectangles, including rectangle 1102, rectangle 1104, rectangle 1106, rectangle 1108, rectangle 1110 and rectangle 1112. Additionally, portions of four additional rectangles are illustrated: rectangle 1114, rectangle 1116, rectangle 1118 and rectangle 1120. As can be seen, the rectangles are arranged in a regular pattern with columns, where adjacent columns are separated by a space 1130, and where adjacent rectangles within a column are separated by a space 1132.

Pattern group 1100 can be written to a surface using conventional non-overlapping VSB shots, using one VSB shot for each pattern in pattern group 1100. FIG. 11A can therefore also be viewed as a group of shots 1100, comprising shots 1102, 1104, 1106, 1108, 1110, 1112, 1114, 1116, 1118, and 1120. FIG. 11B illustrates an example of a set of simulated patterns 1150 that may be produced from shot group 1100, in the presence of mid-range scattering. Set of patterns 1150 comprises six whole patterns, including pattern 1152, pattern 1154, pattern 1156, pattern 1158, pattern 1160 and pattern 1162. Pattern group 1150 also comprises four additional patterns where only a portion of the pattern is illustrated in FIG. 11B, including pattern 1164, pattern 1166, pattern 1168 and pattern 1170. The patterns in pattern group 1150 exhibit corner rounding due to beam blur, one example of which is corner 1172. Additionally, the middle portion, measured in the y-direction, of each pattern in the middle two columns is narrower in the x-direction than is the rest of the pattern, as illustrated by middle portion 1174 of pattern 1158. This narrowing is the result of less mid-range scattering energy reaching the middle portion 1174 of pattern 1158 than reaches other portions of pattern 1158. In pattern 1158, pattern narrowing in region 1174 is caused by the gap between shots 1114 and 1106, and by the gap between shots 1118 and 1112. Less mid-range scattering energy reaches the resist in the vicinity of pattern 1158 opposite these gaps, compared to opposite shots 1114, 1106, 1118 and 1112. Outside column patterns 1152, 1154, 1168, 1162 and 1170 exhibit asymmetrical narrowing because of their having neighboring shots on only one of the left or right sides. Inward-facing sides have a similar narrowing as pattern 1158, as illustrated with narrowing region 1176 of pattern 1162. On outside-facing edges such as edge 1178 of pattern 1162 the lack of a neighboring pattern causes lower mid-range scattering energy to be received along the entire edge, with the consequence that the entire edge 1178 is offset in the −x (negative x) direction, causing the width 1182 of pattern 1162 to be less than width 1180 of pattern 1158. This simulated mid-range scattering is similar in range of effect to the mid-range scattering of reticles for EUV optical lithography, but the mid-range scattering simulated in pattern group 1150 is of a higher intensity than current EUV reticles commonly produce. Pattern group 1150 illustrates how mid-range scattering of a sufficient magnitude can affect patterns written by charged particle beam lithography.

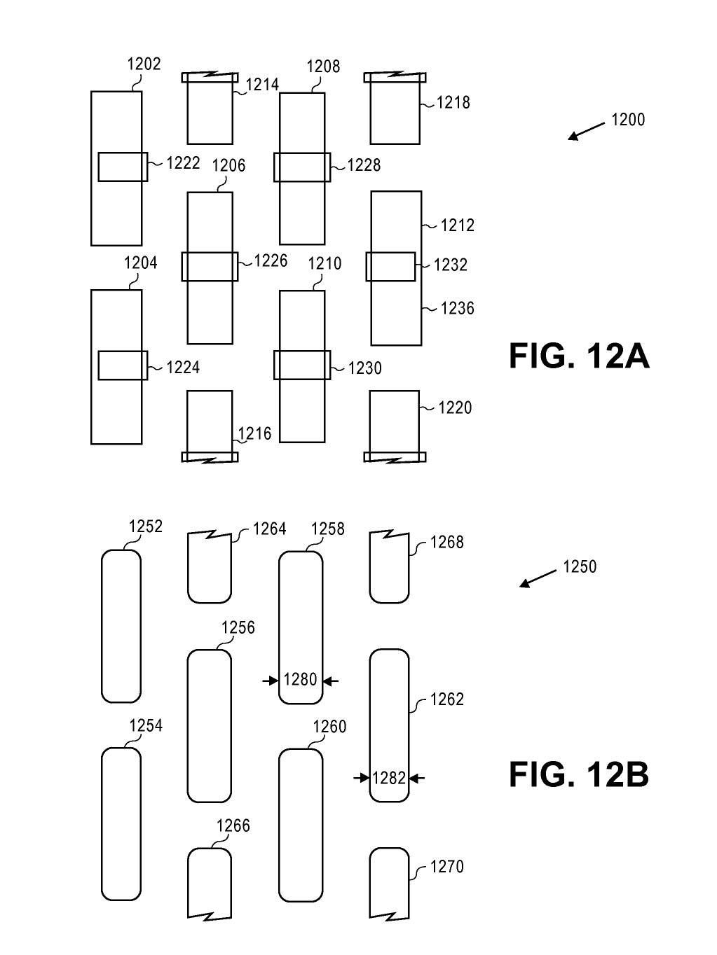

In another embodiment of the current invention, overlapping shots may be used to implement mask process correction, thereby producing higher fidelity patterns in the presence of mid-range scattering. FIG. 12A illustrates a shot group 1200 that may be used to produce the group of patterns 1100. Shot group 1200 comprises rectangular shots 1202, 1204, 1206, 1208, 1210 and 1212. Shot group 1200 also comprises rectangular shots 1214, 1216, 1218 and 1220, only portions of which are illustrated. Compared to shot group 1100, shot group 1200 includes the following:
Shots on the outside columns are widened on their outside edges. This includes shots 1202, 1204, 1218, 1212 and 1220. In shot 1212, for example, edge 1236 has been moved in the +x direction, compared to shot 1112.
Additional shots are added to prevent the pattern narrowing in the middle portion of the patterns as illustrated in pattern group 1150. The added shots include shots 1222, 1224, 1226, 1228, 1230 and 1232. These added shots deliver additional dosage to areas, with the exception of outside edges of outside column shots, that will receive less mid-range scattering dosage. Since on the outside columns of shot group 1200, pattern narrowing is prevented by widening shots 1202, 1204, 1218, 1212 and 1220 on their outside edges as described above, overlapping shots 1222, 1224 and 1232 are positioned away from the outside edges of shots 1202, 1204 and 1212 to prevent excessive middle-portion widening of the patterns formed by shots 1202, 1204 and 1212.

FIG. 12B illustrates an example of a group of patterns 1250 that may be produced on a surface from group of shots 1200. Group of patterns 1250 comprises patterns 1252, 1254, 1256, 1258, 1260 and 1262, and partial patterns 1264, 1266, 1268 and 1270. As can be seen, the exposure changes illustrated in group of shots 1200 compared to group of shots 1100 improve the fidelity of the patterns produced on the surface, in the presence of mid-range scattering. Narrowing of the middle portions of patterns is absent. Additionally, the widths of exterior column patterns, such as width 1282 of pattern 1262, are the same as the widths of interior column patterns, such as width 1280 of pattern 1258.

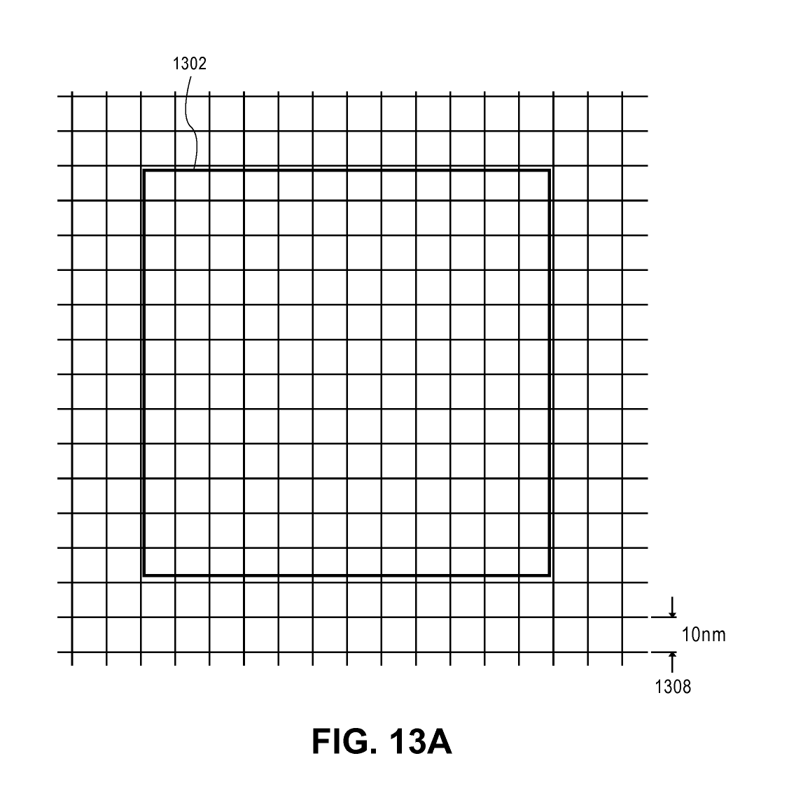

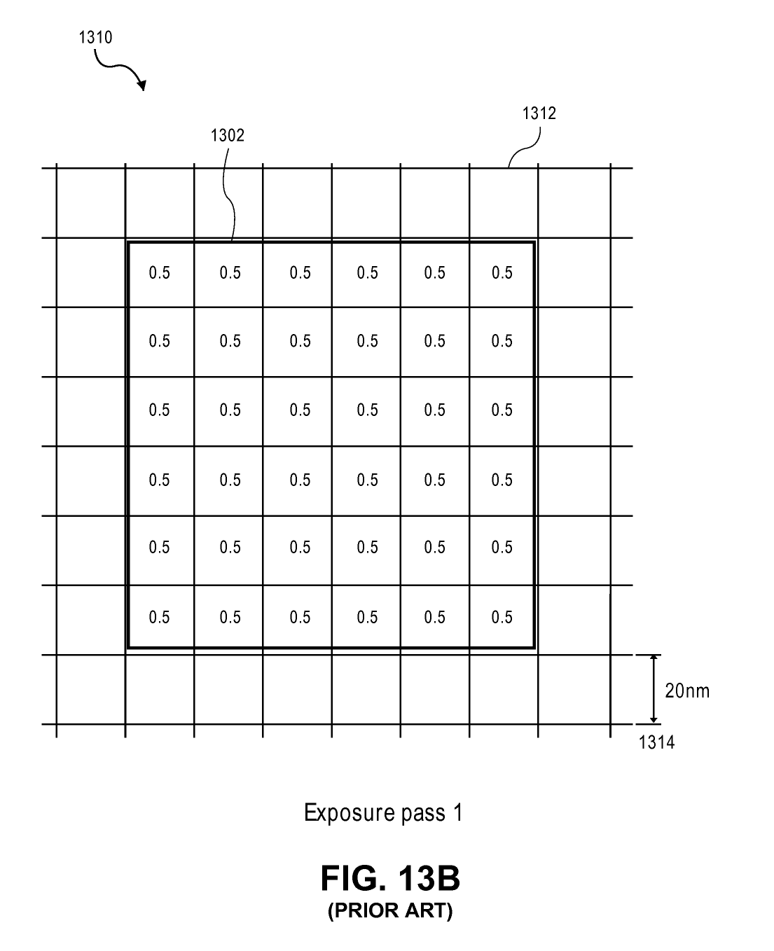

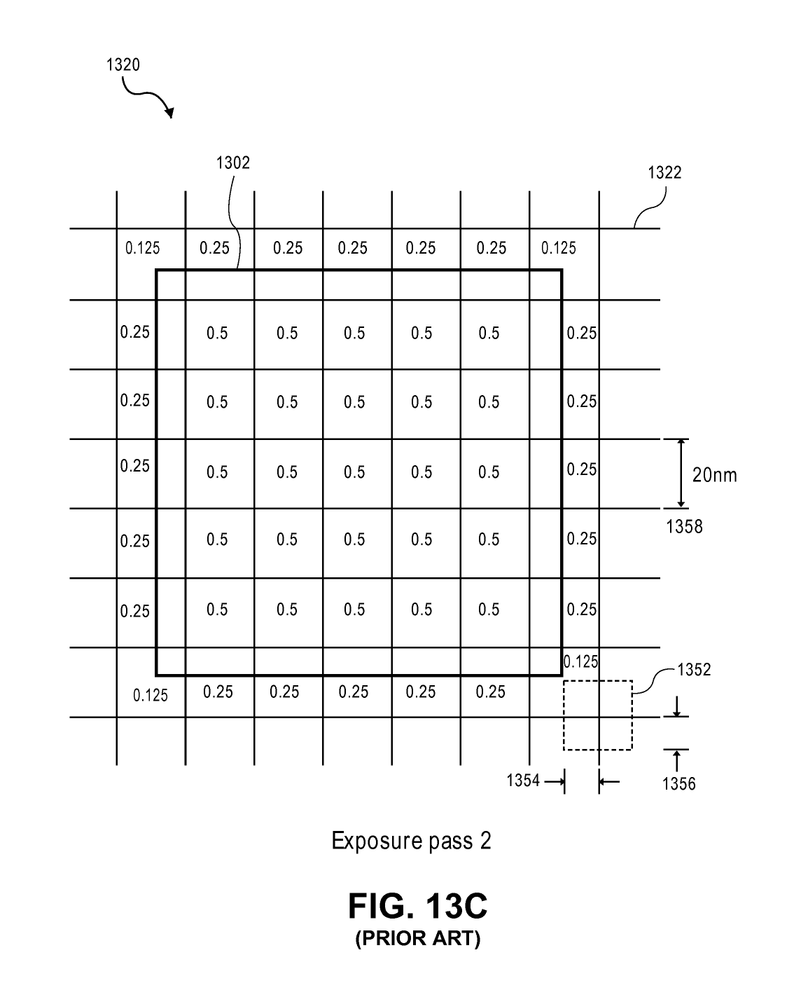

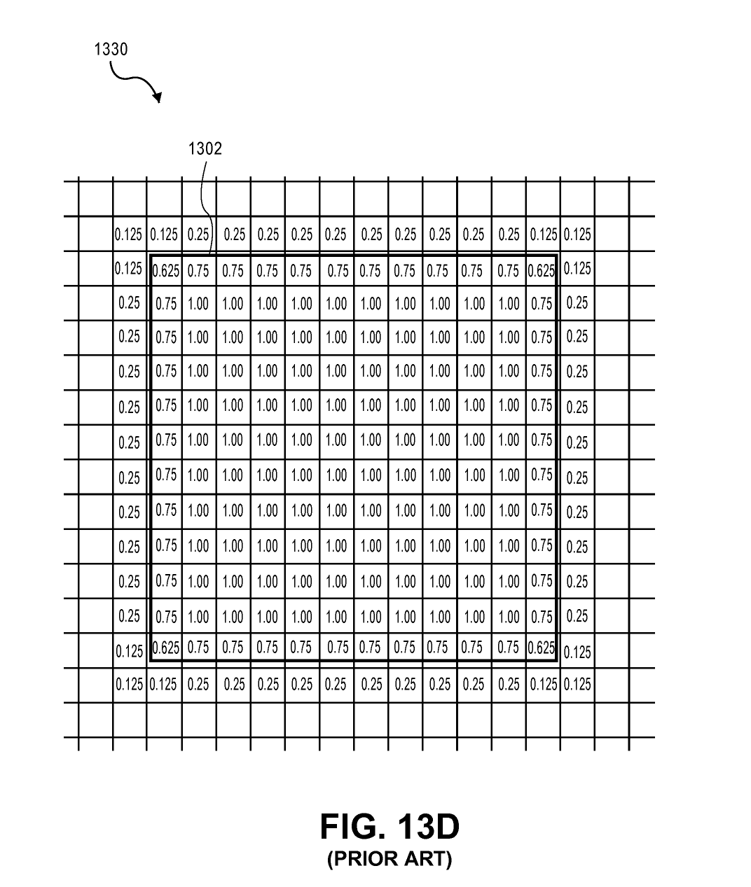

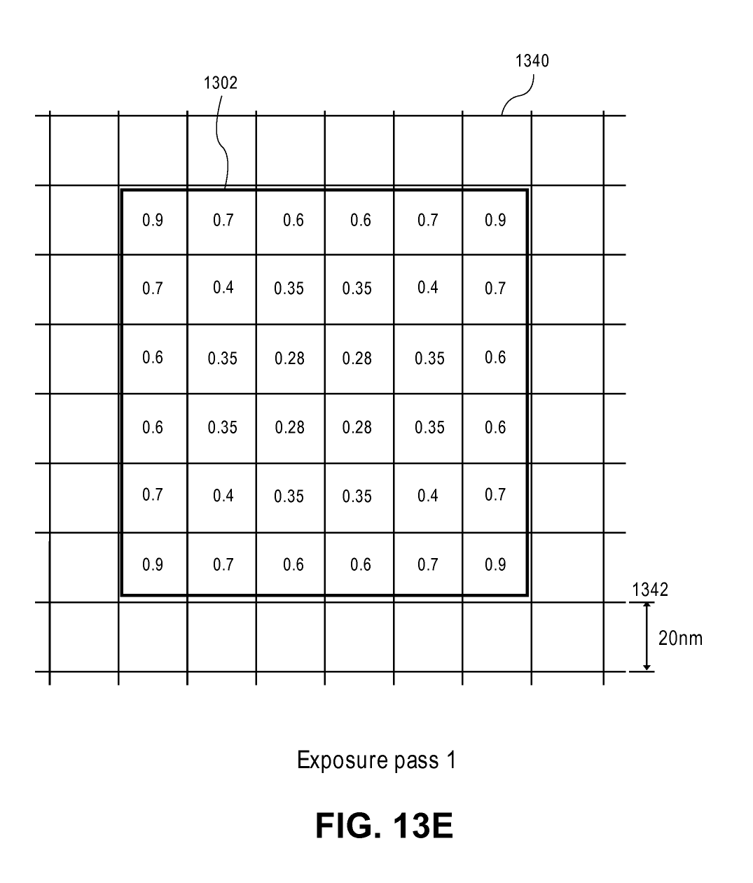

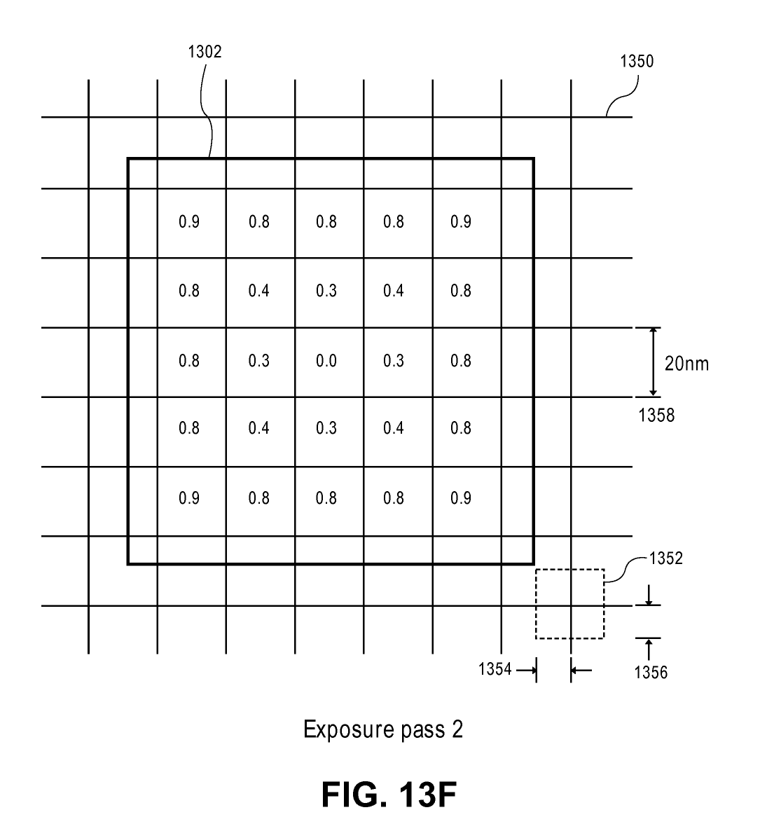

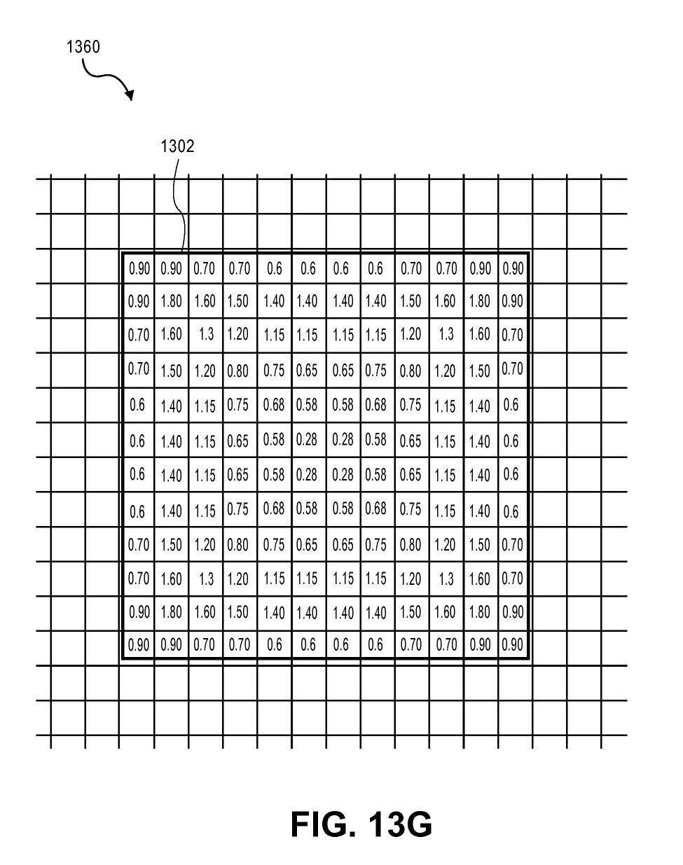

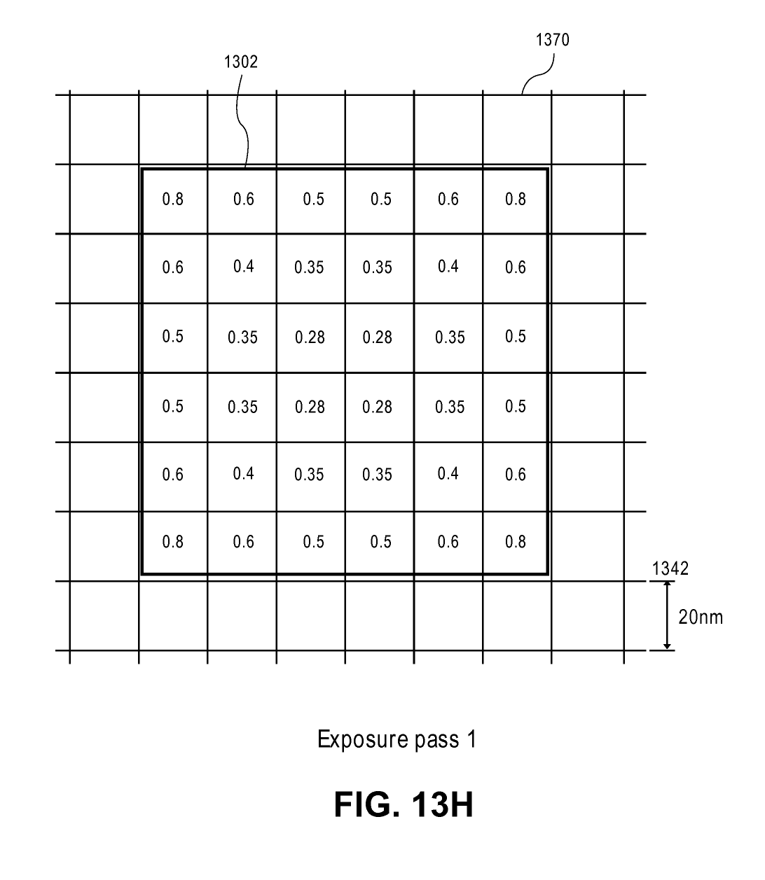

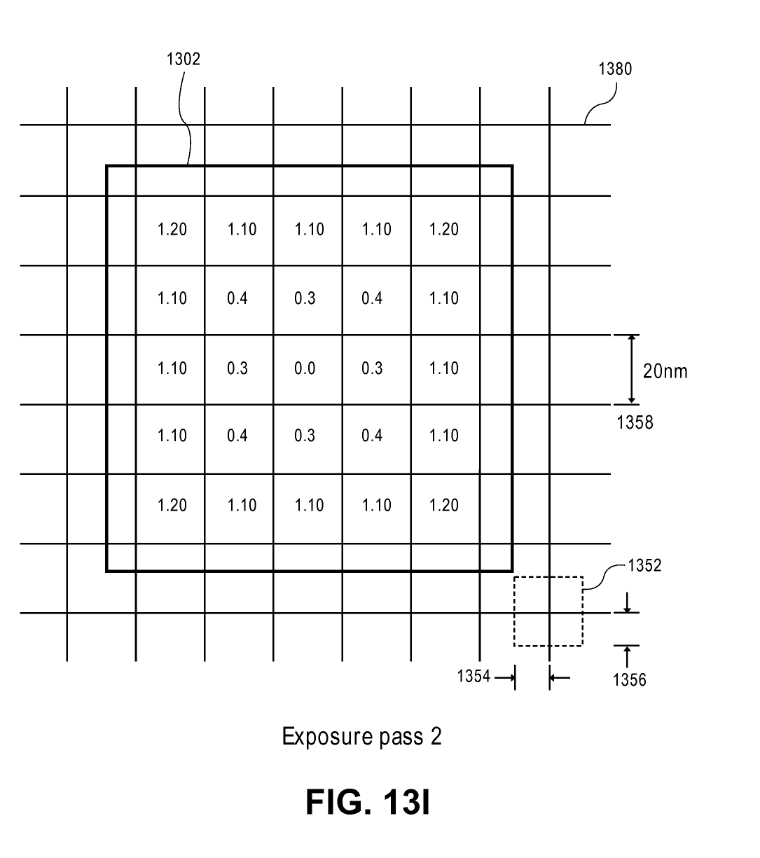

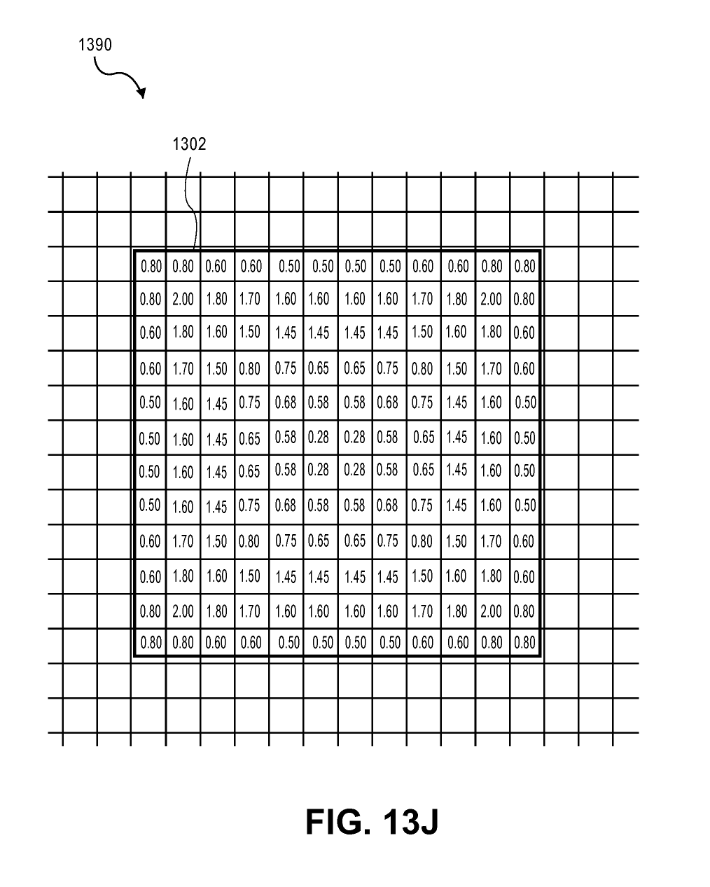

FIG. 13A illustrates an example of a contact or via pattern 1302 that is to be exposed on a resist-coated surface using a multi-beam exposure system, using two exposure passes. In this example the multi-beam exposure system beamlets can expose pixels on a grid with 20 nm pixel spacing. The two exposure passes are offset 10 nm in both x and y, thereby producing an effective exposure grid of 10 nm. The pattern 1302 is superimposed on a 10 nm pixel grid as shown by 1308. In this example, 1.0 is a normal dosage, and the resist threshold is 0.5 times a normal dose. FIGS. 13B & 13C illustrate conventional exposure of pattern 1302. FIG. 13B illustrates conventional exposure for a first exposure pass 1310 of two exposure passes, shown on grid 1312. As can be seen, a dosage of 0.5 times a normal dose is used for all multi-beam beamlets or grids which are within the perimeter of pattern 1302. The perimeter edges of pattern 1302 closely align with the grid squares of exposure grid 1312. Exposure grid 1312 has a grid size 1314 of 20 nm. FIG. 13C illustrates conventional exposure for the second exposure pass 1320, using a pixel grid 1322 in which the grid size 1358 is also 20 nm. Note that the pixel alignment in grid 1322 is offset ½ pixel—10 nm—from pixels in pass 1 exposure grid 1312, in both x and y coordinates. This offset is illustrated by pixel 1352, illustrated in dashed lines, which has pass 1 pixel alignment. The x-offset 1354 and the y-offset 1356 are both 10 nm. The perimeter of pattern 1302 does not align with the boundaries of the grid squares of grid 1322. As can be seen the dosages of pixels which are fully enclosed by pattern 1302 have a 0.5 dosage. Pixels or grid squares which are partially enclosed by pattern 1302 are assigned dosages in proportion to the fraction of each pixel which is enclosed by pattern 1302. FIG. 13D illustrates a calculated combined exposure 1330 for each 10 nm grid based on the exposure from both exposure passes, which in this example is calculated by adding the first pass and second pass dosages. As can be seen, the highest dosage for a pixel is 1.0. The combined exposure 1330 does not display simulated dosage, since no forward scattering effects, such as beam blur, are taken into account.

FIGS. 13E and 13F illustrate an example of exemplary two pass exposure, in which edge slope is increased by varying the dosage of a first beamlet in the plurality of beamlets compared to the dosage of a second beamlet in the plurality of beamlets. FIG. 13E illustrates an example of pixel dosages for pass 1 of 2 exposure passes, using a pixel grid 1340 in which the grid size 1342 is 20 nm. FIG. 13F illustrates an example of pixel dosages for exposure pass 2, using a pixel grid 1350. The size 1358 of pixel grid 1350 is 20 nm. Like in FIG. 13C, grid squares in grid 1350 are offset ½ pixel—10 nm—from pixels in pass 1 exposure grid 1340, in both x and y coordinates. This offset is illustrated by pixel 1352, illustrated in dashed lines, which has pass 1 pixel alignment. The x-offset 1354 and the y-offset 1356 are both 10 nm. FIG. 13G illustrates the combined exposure 1360 of passes 1 and 2, shown on a ½-pixel 10 nm grid. As in FIG. 13D, pass 1 and pass 2 dosages are combined by adding the dosages in each ½-pixel, and not are intended to show dosage received on the surface. Compared to conventional combined dosages 1330, combined dosages 1360 illustrate the following:
The maximum dosage of pixels near the perimeter of pattern 1302 in FIG. 13G is between 1.40 and 1.80, which is higher than the maximum conventional combined dosage of 1.0 of FIG. 13D.
A higher dosage is used in corners. Simulation indicates that this reduces corner rounding.
Pixels which are 20 nm or more toward the interior of pattern 1302 from the highest-dosage pixels have dosage <1.0 in FIG. 13G. This reduces back-scatter contribution. At the very center of the figure, a 1×1 pixel (20 nm×20 nm) area receives only 0.28 times a normal dosage. When beam blur is taken into account, simulation shows that no hole is registered by the resist, even for a manufacturing variation in which the resist threshold was 0.7 times a normal dose, rather than 0.5.
   The beamlet dosages for passes 1 and 2 may be determined using model-based fracturing techniques.

Various solutions are possible which provide elevated dosage near the perimeters of patterns. FIGS. 13H and 13I illustrate another example of exemplary two pass exposure. FIG. 13H illustrates an example of pixel dosages for pass 1 of 2 exposure passes, using a pixel grid 1370 in which the grid size 1342 is 20 nm. FIG. 13I illustrates an example of pixel dosages for exposure pass 2, using a pixel grid 1380. The size 1358 of pixel grid 1350 is 20 nm. Like in FIGS. 13C and 13F, grid squares in grid 1380 are offset ½ pixel—10 nm—from pixels in pass 1 exposure grid 1370, in both x and y coordinates. This offset is illustrated by pixel 1352, illustrated in dashed lines, which has pass 1 pixel alignment. The x-offset 1354 and the y-offset 1356 are both 10 nm. FIG. 13J illustrates the combined exposure 1390 of passes 1 and 2, shown on a ½-pixel 10 nm grid. As in FIGS. 13D and 13G, pass 1 and pass 2 dosages are combined by adding the dosages in each ½-pixel, and not are intended to show dosage received on the surface. Compared to FIG. 13G, the combined half-pixel dosages within 10 nm of the perimeter of pattern 1302 are lower in FIG. 13J than in FIG. 13G. However, the combined half-pixel dosages between 10 nm and 20 nm from the perimeter of pattern 1302 are higher in FIG. 13J than in FIG. 13G, which may produce a higher edge slope in FIG. 13J than in FIG. 13G. Compared to the dosages of FIG. 13G, the dosages of FIG. 13J may produce a pattern that less accurately follows the perimeter of pattern 1302. However, the pattern produced by the dosages of FIG. 13J may display less dimensional variation with manufacturing variation than the pattern produced with dosages of FIG. 13G.

The calculations described or referred to in this invention may be accomplished in various ways. Generally, calculations may be accomplished by in-process, pre-process or post-process methods. In-process calculation involves performing a calculation when its results are needed. Pre-process calculation involves pre-calculating and then storing results for later retrieval during a subsequent processing step, and may improve processing performance, particularly for calculations that may be repeated many times. Calculations may also be deferred from a processing step and then done in a later post-processing step. An example of pre-process calculation is a shot group, which is a pre-calculation of dosage pattern information for one or more shots associated with a given input pattern or set of input pattern characteristics. The shot group and the associated input pattern may be saved in a library of pre-calculated shot groups, so that the set of shots comprising the shot group can be quickly generated for additional instances of the input pattern, without pattern re-calculation. In some embodiments, the pre-calculation may comprise simulation of the dosage pattern that the shot group will produce on a resist-coated surface. In other embodiments, the shot group may be determined without simulation, such as by using correct-by-construction techniques. In some embodiments, the pre-calculated shot groups may be stored in the shot group library in the form of a list of shots. In other embodiments, the pre-calculated shot groups may be stored in the form of computer code that can generate shots for a specific type or types of input patterns. In yet other embodiments, a plurality of pre-calculated shot groups may be stored in the form of a table, where entries in the table correspond to various input patterns or input pattern characteristics such as pattern width, and where each table entry provides either a list of shots in the shot group, or information for how to generate the appropriate set of shots. Additionally, different shot groups may be stored in different forms in the shot group library. In some embodiments, the dosage pattern which a given shot group can produce may also be stored in the shot group library. In one embodiment, the dosage pattern may be stored as a two-dimensional (X and Y) dosage map called a glyph.

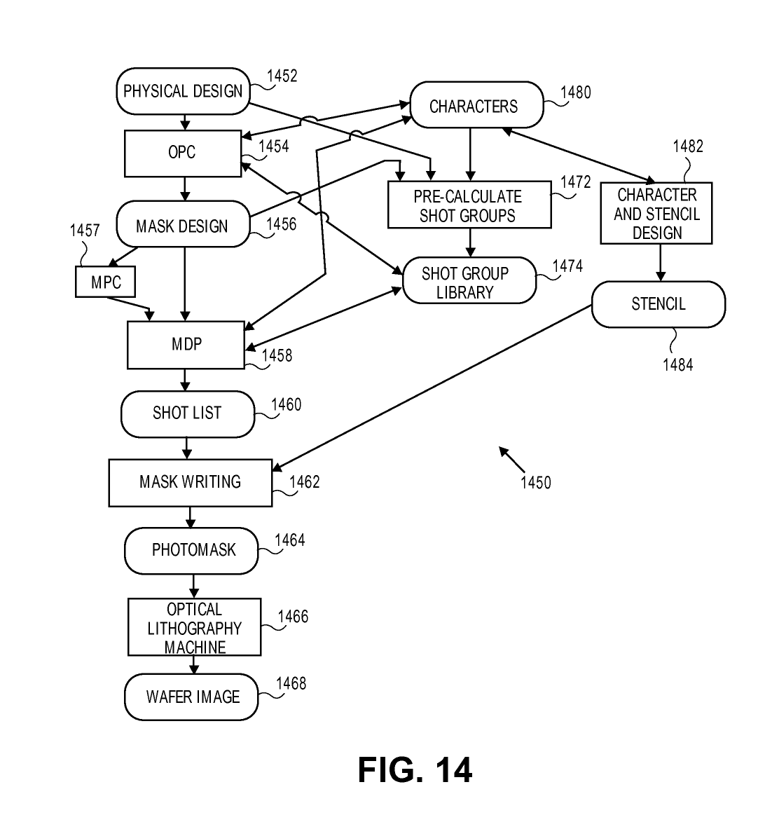

FIG. 14 is a conceptual flow diagram 1450 of how to prepare a reticle for use in fabricating a surface such as an integrated circuit on a silicon wafer. In a first step 1452, a physical design, such as a physical design of an integrated circuit, is designed. This can include determining the logic gates, transistors, metal layers, and other items that are required to be found in a physical design such as that in an integrated circuit. The physical design may be rectilinear, partially curvilinear, or completely curvilinear. Next, in a step 1454, optical proximity correction is determined. In an embodiment of this disclosure, this can include taking as input a library of pre-calculated shot groups from a shot group library 1474. This can also alternatively, or in addition, include taking as input a library of pre-designed characters 1480 including complex characters that are to be available on a stencil 1484 in a step 1462. In an embodiment of this disclosure, an OPC step 1454 may also include simultaneous optimization of shot count or write times, and may also include a fracturing operation, a shot placement operation, a dose assignment operation, or may also include a shot sequence optimization operation, or other mask data preparation operations, with some or all of these operations being simultaneous or combined in a single step. The OPC step may create partially or completely curvilinear patterns. The output of the OPC step 1454 is a mask design 1456.

Mask process correction (MPC) 1457 may optionally be performed on the mask design 1456. MPC modifies the pattern to be written to the reticle, compensating for effects such as the narrowing of patterns which are less than about 100 nm wide. In a step 1458, a mask data preparation (MDP) operation which may include a fracturing operation, a shot placement operation, a dose assignment operation, or a shot sequence optimization may take place. MDP may use as input the mask design 1456 or the results of MPC 1457. In some embodiments of the present invention, MPC may be performed as part of a fracturing or other MDP operation. Other corrections may also be performed as part of fracturing or other MDP operation, the possible corrections including: forward scattering, resist diffusion, Coulomb effect, etching, backward scattering, fogging, loading, resist charging, and EUV mid-range scattering. MDP may comprise determining a set of multi-beam shots, where each multi-beam shot comprises a plurality of beamlets. In some embodiments, the set of multi-beam shots my comprise shots for a plurality of exposure passes. In one embodiment, the plurality of exposure passes comprises a first pass and a second pass, where the multi-beam shots in the first pass are offset from the multi-beam shots in the second pass by a distance which is a fraction of the pixel spacing between adjacent beamlets. The result of MDP step 1458 is a shot list 1460. Either the OPC step 1454 or of the MDP step 1458, or a separate program 1472 can include pre-calculating one or more shot groups that may be used for a given input pattern, and storing this information in a shot group library 1474. Combining OPC and any or all of the various operations of mask data preparation in one step is contemplated in this disclosure. Mask data preparation step 1458, which may include a fracturing operation, may also comprise a pattern matching operation to match pre-calculated shot groups to create a mask that matches closely to the mask design. Mask data preparation may also comprise reducing the sensitivity of the pattern written in step 1462 to manufacturing variation, which in some embodiments may comprises increasing edge slope. Mask data preparation may also comprise inputting patterns to be formed on a surface with the patterns being slightly different, selecting a set of characters to be used to form the number of patterns, the set of characters fitting on a stencil mask, the set of characters possibly including both complex and VSB characters, and the set of characters based on varying character dose or varying character position or varying the beam blur radius or applying partial exposure of a character within the set of characters or dragging a character to reduce the shot count or total write time. A set of slightly different patterns on the surface may be designed to produce substantially the same pattern on a substrate. Also, the set of characters may be selected from a predetermined set of characters. In one embodiment of this disclosure, a set of characters available on a stencil in a step 1480 that may be selected quickly during the mask writing step 1462 may be prepared for a specific mask design. In that embodiment, once the mask data preparation step 1458 is completed, a stencil is prepared in a step 1484. In another embodiment of this disclosure, a stencil is prepared in the step 1484 prior to or simultaneous with the MDP step 1458 and may be independent of the particular mask design. In this embodiment, the characters available in the step 1480 and the stencil layout are designed in step 1482 to output generically for many potential mask designs 1456 to incorporate patterns that are likely to be output by a particular OPC program 1454 or a particular MDP program 1458 or particular types of designs that characterizes the physical design 1452 such as memories, flash memories, system on chip designs, or particular process technology being designed to in physical design 1452, or a particular cell library used in physical design 1452, or any other common characteristics that may form different sets of slightly different patterns in mask design 1456. The stencil can include a set of characters, such as a limited number of characters that was determined in the step 1458.

The shot list 1460 is used to generate a surface in a mask writing step 1462, which uses a charged particle beam writer such as an electron beam writer system. Mask writing step 1462 may use stencil 1484 containing a plurality of complex characters, or may use a stencil comprising only VSB apertures, or may use a multi-beam system with either shaped beamlets or unshaped beamlets. The electron beam writer system projects a beam of electrons onto a surface to form patterns in a surface, as shown in a step 1464. One exposure pass or a plurality of exposure passes may be used to form the patterns on the surface. The completed surface may then be used in an optical lithography machine, which is shown in a step 1466. Finally, in a step 1468, a substrate such as a silicon wafer is produced. As has been previously described, in step 1480 characters may be provided to the OPC step 1454 or the MDP step 1458. The step 1480 also provides characters to a character and stencil design step 1482 or a shot group generation step 1472. The character and stencil design step 1482 provides input to the stencil step 1484 and to the characters step 1480. The shot group generation step 1472 provides information to the shot group library 1474. Also, a shot group pre-calculation step 1472 may use as input the physical design 1452 or the mask design 1456, and may pre-calculate one or more shot groups, which are stored in a shot group library 1474.

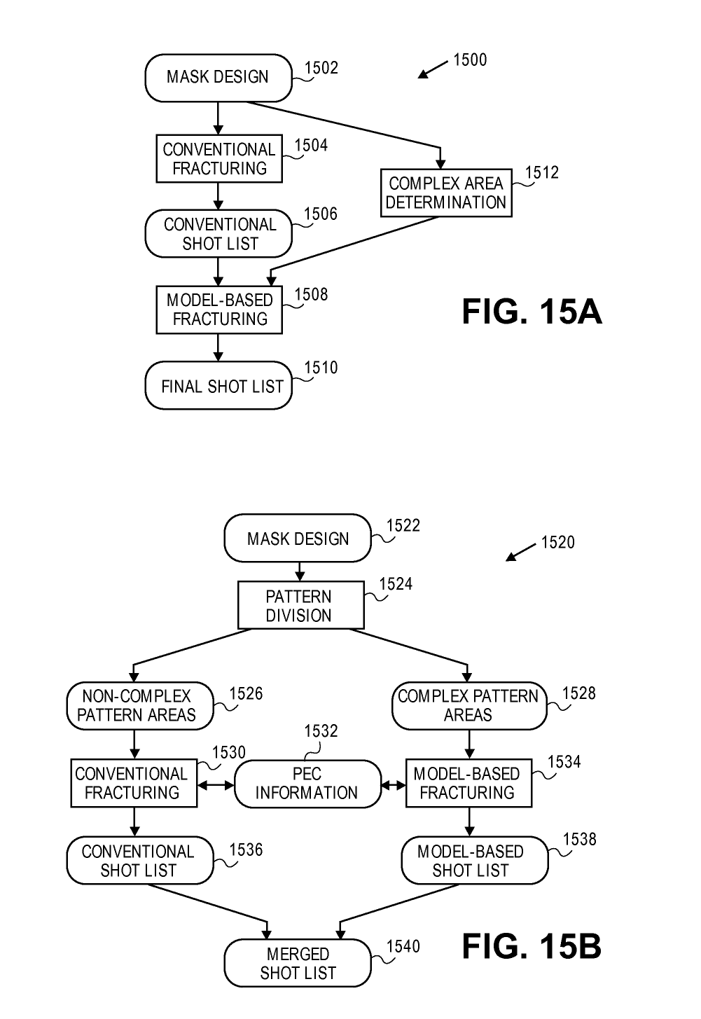

Model-based fracturing may be combined with conventional fracturing in a single design. This allows, for example, model-based fracturing to be used in those areas where it can provide the greatest benefit, while using conventional fracturing, which is less computationally intensive, for other parts of the design. As previously indicated, in conventional fracturing, shot overlap is avoided whenever possible, and all shots have a normal dosage before long-range correction. In FIG. 15A conceptual flow diagram 1500 illustrates one embodiment for how conventional and model-based fracturing may be combined. The input to the combined fracturing process is mask design 1502. Mask design 1502 may be mask design 1456 from FIG. 14, or it may be a part of mask design 1456, or an altered form of mask design 1456 such as from MPC 1457. Conventional fracturing 1504 is performed on the mask design 1502 to create a conventional shot list 1506. Alternatively, conventional fracturing may be performed on parts of the mask design 1502, leaving some parts unfractured. A model-based fracturing step 1508 then inputs the shot list 1506 and modifies, adds, or deletes shots in complex areas of a design. Complex areas may include, for example, areas with the smallest patterns, or areas with curvilinear patterns. Complex areas may also include areas with high influence from mid-range scattering. Complex areas may also include “hot spots” of particular sensitivity in manufacturing. The word “complex” in this context may not mean geometric complexity of the shapes. In some embodiments, the model-based fracturing 1508 may include determining in which areas to modify and/or replace conventional shots with model-base shots. In other embodiments the complex areas may be determined in a separate step 1512, either automatically from mask design 1456, or manually. In any case, model-based fracturing 1508 generates shots, some of which partially overlap other shots. The model-based fracturing may replace or modify some or all of the conventional shots in the designated or determined complex portions of the design with shots that have been determined using model-based techniques. The output of the model-based fracturing step 1508 is a final shot list 1510, containing both conventional and model-based shots. Final shot list 1508 corresponds to FIG. 14 shot list 1460. With regard to coarse grain parallel processing of the steps in conceptual flow diagram 1500, the mask design 1502 may be a partial design, or it may be the entire design where each of the steps may be performed in parallel.

FIG. 15B conceptual flow diagram 1520 illustrates another embodiment of how conventional and model-based fracturing may be combined. The input to the combined fracturing process is mask design 1522. Mask design 1522 may be mask design 1456 from FIG. 14, or it may be a part of mask design 1456, or an altered form of mask design 1456 such as from MPC 1457. In FIG. 15B the mask design 1522 is processed by pattern division step 1524, which separates the pattern data into non-complex pattern area 1526 and complex pattern area 1528. A conventional fracturing step 1530 uses the non-complex pattern area 1526 as input. The conventional fracturing 1530 outputs a list of conventional shots 1536. An additional output is PEC information 1532. In some embodiments this information may be one or more forms directly usable by PEC. In other embodiments, the PEC information may be, for example, the conventional shot list itself, from which PEC information may be calculated. The complex pattern area 1528 is fractured using model-based fracturing 1534. Model-based fracturing 1534 may use the PEC information 1532 as input, processing this information if necessary to derive the appropriate PEC corrections for the model-based shots which are within the influence range of the long-range effects from the conventional shots. In other embodiments, the PEC information may also be output by model-based fracturing 1534, and conventional fracturing 1530 may use this information in some way. Model-based fracturing 1534 creates a model-based shot list 1538. The conventional shot list 1536 and the model-based shot list 1538 are then merged into a merged shot list 1540, which corresponds to FIG. 14 shot list 1460. With regard to coarse grain parallel processing of the steps in conceptual flow diagram 1520, the mask design 1522 may be a partial design, or it may be the entire design where each of the steps may be performed in parallel.

The fracturing, mask data preparation, proximity effect correction and shot group creation flows described in this disclosure may be implemented using general-purpose computers with appropriate computer software as computation devices. Due to the large amount of calculations required, multiple computers or processor cores may also be used in parallel. In one embodiment, the computations may be subdivided into a plurality of 2-dimensional geometric regions for one or more computation-intensive steps in the flow, to support parallel processing. In another embodiment, a special-purpose hardware device, either used singly or in multiples, may be used to perform the computations of one or more steps with greater speed than using general-purpose computers or processor cores. In one embodiment, the special-purpose hardware device may be a graphics processing unit (GPU). In another embodiment, the optimization and simulation processes described in this disclosure may include iterative processes of revising and recalculating possible solutions, so as to minimize either the total number of shots, or the total charged particle beam writing time, or some other parameter. In yet another embodiment, an initial set of shots may be determined in a correct-by-construction method, so that no shot modifications are required.

While the specification has been described in detail with respect to specific embodiments, it will be appreciated that those skilled in the art, upon attaining an understanding of the foregoing, may readily conceive of alterations to, variations of, and equivalents to these embodiments. These and other modifications and variations to the present methods for fracturing, mask data preparation, proximity effect correction and optical proximity correction may be practiced by those of ordinary skill in the art, without departing from the scope of the present subject matter, which is more particularly set forth in the appended claims. Furthermore, those of ordinary skill in the art will appreciate that the foregoing description is by way of example only, and is not intended to be limiting. Steps can be added to, taken from or modified from the steps in this specification without deviating from the scope of the invention. In general, any flowcharts presented are only intended to indicate one possible sequence of basic operations to achieve a function, and many variations are possible. Thus, it is intended that the present subject matter covers such modifications and variations as come within the scope of the appended claims and their equivalents.

What is claimed is:

1. A method for fracturing or mask data preparation or mask process correction or proximity effect correction for charged particle beam lithography, the method comprising:
determining a plurality of charged particle beam shots that will form a pattern on a surface using a multi-beam charged particle beam writer;
wherein each charged particle beam shot is a multi-beam shot comprising a plurality of beamlets;
wherein a sensitivity of the pattern on the surface to manufacturing variation is reduced by increasing edge slope; and
wherein the step of determining is performed using one or more computing hardware processors.

2. The method of claim 1 wherein the determining comprises calculating the pattern on the surface from the plurality of charged particle beam shots.

3. The method of claim 2 wherein the calculating comprises charged particle beam simulation.

4. The method of claim 3 wherein the charged particle beam simulation includes at least one of a group of short-range effects consisting of forward scattering, resist diffusion, Coulomb effect, and etching.

5. The method of claim 3 wherein the surface is an extreme ultraviolet (EUV) reticle, and wherein the charged particle beam simulation includes EUV mid-range scattering.

6. The method of claim 1 wherein the edge slope is increased by varying the dosage of a first beamlet in the plurality of beamlets compared to the dosage of a second beamlet in the plurality of beamlets.

7. The method of claim 1 wherein the plurality of charged particle beam shots comprises a plurality of multi-beam shots in each of a plurality of exposure passes.

8. The method of claim 7 wherein a first distance between adjacent beamlets in the plurality of beamlets comprises a pixel spacing, wherein the plurality of exposure passes comprises a first pass and a second pass, and wherein multi-beam shots in the first pass are offset from multi-beam shots in the second pass by a second distance which is a fractional pixel spacing.

9. The method of claim 8 wherein the second distance is one-half of a pixel spacing.

10. A method for manufacturing a surface using charged particle beam lithography, the method comprising:
determining a plurality of charged particle beam shots that will form a pattern on a surface using a multi-beam charged particle beam writer; and
forming the pattern on the surface with the plurality of charged particle beam shots;
wherein each charged particle beam shot is a multi-beam shot comprising a plurality of beamlets;
wherein the sensitivity of the pattern on the surface to manufacturing variation is reduced by increasing edge slope; and
wherein the step of determining is performed using one or more computing hardware processors.

11. The method of claim 10 wherein the determining comprises calculating the pattern on the surface from the plurality of charged particle beam shots.

12. The method of claim 11 wherein the calculation comprises charged particle beam simulation.

13. The method of claim 12 wherein the charged particle beam simulation includes at least one of a group of short-range effects consisting of forward scattering, resist diffusion, Coulomb effect, and etching.

14. The method of claim 12 wherein the surface is an extreme ultraviolet (EUV) reticle, and wherein the charged particle beam simulation includes EUV mid-range scattering.

15. The method of claim 10 wherein the edge slope is increased by varying the dosage of a first beamlet in the plurality of beamlets compared to the dosage of a second beamlet in the plurality of beamlets.

16. The method of claim 10 wherein the plurality of charged particle beam shots comprises a plurality of multi-beam shots in each of a plurality of exposure passes.

17. A method for manufacturing an integrated circuit using an optical lithographic process, the optical lithographic process using a reticle manufactured with charged particle beam lithography, the method comprising:
determining a plurality of charged particle beam shots that will form a pattern on the reticle using a multi-beam charged particle beam writer; and
forming the pattern on the reticle with the plurality of charged particle beam shots;
wherein each charged particle beam shot is a multi-beam shot comprising a plurality of beamlets;
wherein the sensitivity of the pattern on the reticle to manufacturing variation is reduced by increasing edge slope; and
wherein the step of determining is performed using one or more computing hardware processors.

18. The method of claim 17 wherein the determining comprises calculating the pattern on the reticle from the plurality of charged particle beam shots.

19. The method of claim 18 wherein the calculation comprises charged particle beam simulation.

20. The method of claim 19 wherein the charged particle beam simulation includes at least one of a group of short-range effects consisting of forward scattering, resist diffusion, Coulomb effect, and etching.

21. The method of claim 19 wherein the reticle is an extreme ultraviolet (EUV) reticle, and wherein the charged particle beam simulation includes EUV mid-range scattering.

22. The method of claim 17 wherein the edge slope is increased by varying the dosage of a first beamlet in the plurality of beamlets compared to the dosage of a second beamlet in the plurality of beamlets.

23. The method of claim 17 wherein the plurality of charged particle beam shots comprises a plurality of multi-beam shots in each of a plurality of exposure passes.

24. A system for fracturing or mask data preparation or mask process correction or proximity effect correction for charged particle beam lithography comprising:
a device configured to determine a plurality of charged particle beam shots that will form a pattern on a surface using a multi-beam charged particle beam writer;
wherein each charged particle beam shot is a multi-beam shot comprising a plurality of beamlets; and
wherein the sensitivity of the pattern on the surface to manufacturing variation is reduced by increasing edge slope.

25. The system of claim 24 further comprising a device configured to calculate the pattern on the surface from the plurality of charged particle beam shots.

26. The system of claim 25 wherein the device configured to calculate performs charged particle beam simulation.
